(19) United States
(12) Patent Application Publication
(10) Pub. No.: US 2025/0331180 A1
(43) Pub. Date: Oct. 23, 2025

(54) MEMORY DEVICE, METHOD OF MANUFACTURING MEMORY DEVICE, AND METHOD OF OPERATING MEMORY DEVICE

(71) Applicant: SK hynix Inc., Icheon-si Gyeonggi-do (KR)

(72) Inventor: In Ku KANG, Icheon-si Gyeonggi-do (KR)

(73) Assignee: SK hynix Inc., Icheon-si Gyeonggi-do (KR)

(21) Appl. No.: 18/937,798

(22) Filed: Nov. 5, 2024

(30) Foreign Application Priority Data
Apr. 22, 2024 (KR) 10-2024-0053526

(51) Int. Cl. H10B 43/27

(52) U.S. Cl. CPC H10B 43/27

(57) ABSTRACT

An embodiment includes a memory device, a method of manufacturing the memory device, and a method of operating the memory device. The memory device includes a channel layer, a blocking layer surrounding the channel layer, a plurality of charge trap layers spaced apart from each other and arranged along a surface of the blocking layer, a plurality of tunnel insulating layers, each of the plurality of tunnel insulating layers contacting a different one of the plurality of charge trap layers, and a plurality of gate lines, each of the plurality of gate lines contacting a different one of the plurality of tunnel insulating layers, and each of the plurality of tunnel insulating layers is positioned between a different one of the plurality of charge trap layers and a different one of the plurality of gate lines.

### CROSS-REFERENCE TO RELATED APPLICATION

The present application claims priority under 35 U.S.C. § 119 (a) to Korean patent application number 10-2024-0053526 filed on Apr. 22, 2024, in the Korean Intellectual Property Office, the entire contents of which application is incorporated herein by reference.

### BACKGROUND

### 1. Technical Field

The present disclosure relates to a memory device, a method of manufacturing the memory device, and a method of operating the memory device, including but not limited to a memory device having a three-dimensional structure, a method of manufacturing the memory device, and a method of operating the memory device.

### 2. Description of Related Art

A memory device includes a memory cell array in which data is stored, and a peripheral circuit configured to perform a program, read, or erase operation of the memory cell array.

The memory cell array includes memory blocks, and the memory blocks may be formed in a two-dimensional or three-dimensional structure.

The memory block formed in the two-dimensional structure may include memory cells arranged along a substrate. The memory block formed in the three-dimensional structure may include memory cells stacked in a vertical direction on a substrate. The memory cells of the memory block formed in the three-dimensional structure may be programmed according a method of trapping a charge in a charge trap layer.

### SUMMARY

According to an embodiment of the present disclosure, a memory device includes a channel layer, a blocking layer surrounding the channel layer, a plurality of charge trap layers spaced apart from each other and arranged along the blocking layer, a plurality of tunnel insulating layers, each of the plurality of tunnel insulating layers contacting a different one of the plurality of charge trap layers, and a plurality of gate lines, each of the plurality of gate lines contacting a different one of the plurality of tunnel insulating layers, and each of the plurality of tunnel insulating layers is positioned between a different one of the plurality of charge trap layers and a different one of the plurality of gate lines.

According to an embodiment of the present disclosure, a method of manufacturing a memory device includes alternately stacking a plurality of first material layers with a plurality of second material layers, forming an opening in the first material layers and the second material layers to expose areas of the first material layers and the second material layers, forming recesses between the plurality of first material layers and the plurality of second material layers by removing sections of the second material layers exposed through the opening, forming in each of the recesses a tunnel insulating layer contacting one of the second material layers and a charge trap layer contacting the tunnel insulating layer, forming a blocking layer along a surface of the charge trap layer and the plurality of first material layers exposed through the opening, and forming a channel layer along a surface of the blocking layer.

According to an embodiment of the present disclosure, a method of operating a memory device includes applying a program voltage at a negative voltage level to a selected word line among a plurality of word lines connected to a memory block, applying a pass voltage at a positive voltage level to unselected word lines among the a plurality of word lines, applying a program allowable voltage to selected bit lines among a plurality of bit lines connected to the memory block, and applying a program inhibit voltage to unselected bit lines among the plurality of bit lines.

According to an embodiment of the present disclosure, a method of operating a memory device includes applying an erase voltage at a positive voltage level to a plurality of word lines connected to a memory block, and applying a bit line voltage to a plurality of bit lines connected to the memory block.

According to an embodiment of the present disclosure, a memory device includes a blocking layer surrounding a channel layer; a plurality of charge trap layers spaced apart and arranged along a surface of the blocking layer, each of the plurality of charge trap layers comprising a protrusion extending toward the blocking layer; a plurality of tunnel insulating layers, each of the plurality of tunnel insulating layers contacting a different one of the plurality of charge trap layers; and a plurality of gate lines, each of the plurality of gate lines contacting a different one of the plurality of tunnel insulating layers.

### BRIEF DESCRIPTION OF THE DRAWINGS

FIG. 1 is a diagram illustrating a memory device according to an embodiment of the present disclosure.

FIG. 2 is a diagram illustrating a memory cell array according to an embodiment of the present disclosure.

FIG. 3 is a circuit diagram illustrating a memory block according to an embodiment of the present disclosure.

FIG. 4A and FIG. 4B are diagrams illustrating views of a first structure of a memory device according to an embodiment of the present disclosure.

FIG. 5A to FIG. 5H are diagrams illustrating views of a first structure of a memory device formed utilizing a first method of manufacturing the first structure.

FIG. 6A to FIG. 6J are diagrams illustrating views of a first structure of a memory device formed utilizing a second method of manufacturing the first structure.

FIG. 7 is a diagram illustrating a second structure of a memory device according to an embodiment of the present disclosure.

FIG. 8A to FIG. 8I are diagrams illustrating views of a second structure of a memory device formed utilizing a first method of manufacturing the second structure.

FIG. 9A to FIG. 9K are diagrams illustrating views of a second structure of a memory device formed utilizing a second method of manufacturing the second structure.

FIG. 10A and FIG. 10B are diagrams illustrating views of a memory block and a section of a first structure during a program operation of a program method according to an embodiment of the present disclosure.

FIG. 11A and FIG. 11B are diagrams illustrating views of a memory block and a section of a first structure during an erase operation of an erasure method according to an embodiment of the present disclosure.

FIG. 12A and FIG. 12B are diagrams illustrating a read method according to an embodiment of the present disclosure.

FIG. 13 is a diagram illustrating a solid state drive SSD system including the memory device of the present disclosure.

FIG. 14 is a diagram illustrating a memory card system including the memory device of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be referred to as a second element in one example, and the second element may be referred to as a first element in another example. When one element is identified as “connected” to another element, the elements may be connected directly or through an intervening element between the elements. When two elements are identified as “directly connected,” one element is directly connected to the other element without an intervening element between the two elements.

Terms such as “vertical,” “top,” “bottom,” “on,” “side,” “upper,” “lower,” “higher,” column,” “row,” “level,” and other terms implying relative spatial relationship or orientation are utilized only for the purpose of ease of description or reference to a drawing and are not otherwise limiting.

In a three-dimensional memory device, the charge trap layer may extend in the vertical direction. Because different memory cells trap a charge in different regions of the charge trap layer extending the vertical direction, interference may increase between consecutive memory cells in the vertical direction, a retention characteristic that benefits from a threshold voltage of programmed memory cells to be maintained may deteriorate. An embodiment of the present disclosure provides a memory device in which a retention characteristic of memory cells may be improved and a method of manufacturing the memory device.

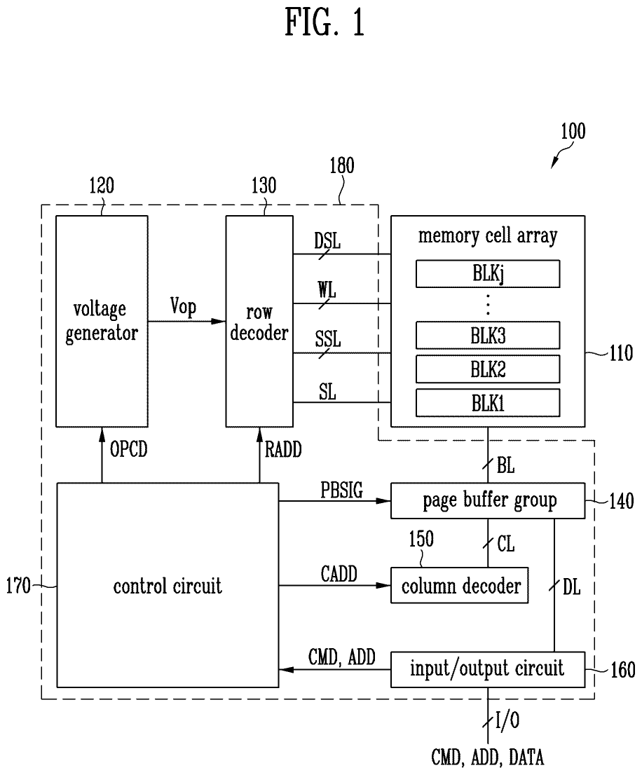

FIG. 1 is a diagram illustrating a memory device.

Referring to FIG. 1, the memory device 100 includes a memory cell array 110 and a peripheral circuit 180.

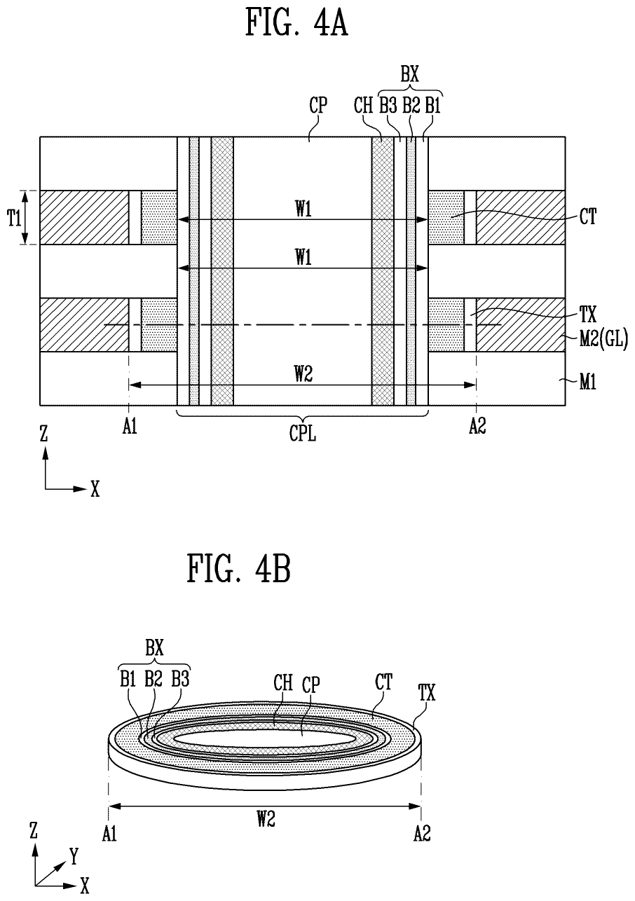

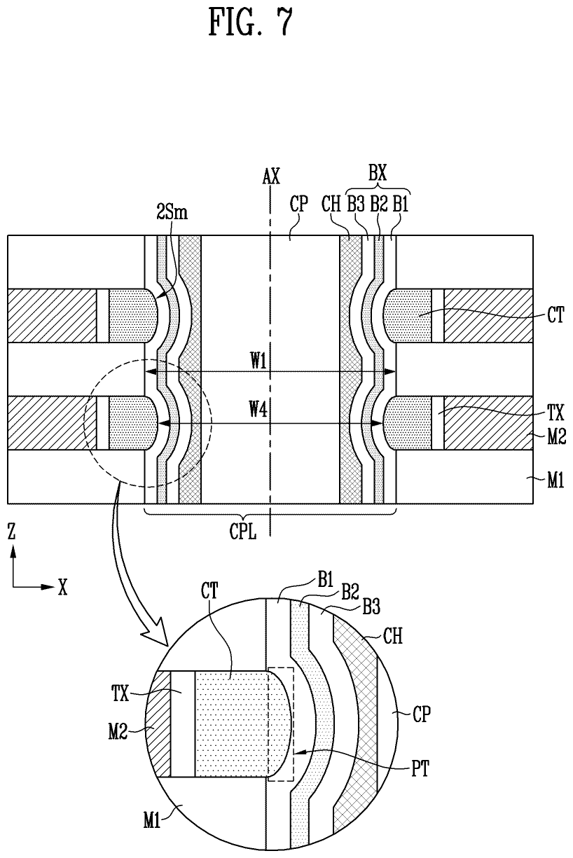

The memory cell array 110 includes first memory block BLK1 to j-th memory block BLKj, where j is a positive integer. Each of the memory blocks BLK1 to BLKj includes memory cells capable of storing data. Drain select lines DSL, word lines WL, source select lines SSL, and a source line SL are connected to each of the memory blocks BLK1 to BLKj, and a bit line BL is commonly connected to the memory blocks BLK1 to BLKj. The memory blocks BLK1 to BLKj may correspond to the memory blocks shown in FIG. 4A. The memory blocks BLK1 to BLKj may correspond to the memory blocks shown in FIG. 7.

The memory blocks BLK1 to BLKj may be formed in a two-dimensional structure or a three-dimensional structure. The memory blocks having a two-dimensional structure may include memory cells arranged in parallel on a substrate. The memory blocks having a three-dimensional structure may include memory cells stacked on a substrate in a vertical direction. Memory blocks formed in a three-dimensional structure are disclosed as an embodiment of the present disclosure.

The memory cells store 1 or more bits of data according to a program method. For example, a method in which 1 bit of data is stored in one memory cell is referred to as a single level cell method, and a method in which 2 bits of data are stored in one memory cell is referred to as a multi-level cell method. A method in which 3 bits of data is stored in one memory cell is referred to as a triple level cell method, and a method in which 4 bits of data is stored in one memory cell is referred to as a quad level cell method. Five bits or more of data may be stored in one memory cell.

The peripheral circuit 180 is configured to perform the program operation including storing data in the memory cell array 110, the read operation including outputting the data stored in the memory cell array 110, and the erase operation including erasing the data stored in the memory cell array 110. For example, the peripheral circuit 180 includes a voltage generator 120, a row decoder 130, a page buffer group 140, a column decoder 150, an input/output circuit 160, and a control circuit 170.

The voltage generator 120 generates various operation voltages Vop used during the program operation, the read operation, and the erase operation in response to an operation code OPCD. For example, the voltage generator 120 is configured to generate a program voltage, a turn-on voltage, a turn-off voltage, a verify voltage, a read voltage, a pass voltage, and an erase voltage in response to the operation code OPCD. Each of the operation voltages Vop generated by the voltage generator 120 may have various voltage levels. The operation voltages Vop generated by the voltage generator 120 are applied to the drain select lines DSL, the word lines WL, the source select lines SSL, and the source line SL of memory block selected through the row decoder 130.

The program voltage includes a voltage applied to a selected word line among the word lines WL during the program operation and is used to increase a threshold voltage of memory cells connected to the selected word line. The turn-on voltage is applied to the drain select lines DSL or the source select lines SSL and is used to turn on drain select transistors or source select transistors. The turn-off voltage is applied to the drain select lines DSL or the source select lines SSL and is used to turn off the drain select transistors and the source select transistors. The verify voltage is used during a verify operation that determines whether a threshold voltage of selected memory cells is increased to a target level. The verify voltages are set to various levels according to the target level and are applied to the selected word line. The read voltage is applied to the selected word line during the read operation of the selected memory cells. For example, the read voltage is set to various levels according to a program method of the selected memory cells. The pass voltage includes a voltage applied to unselected word lines among the word lines WL during the program or read operation and is used to turn on memory cells connected to the unselected word lines. The erase voltage is used during the erase operation to erase memory cells included in the selected memory block and is applied to the word lines WL.

The row decoder 130 is configured to transmit the operation voltages Vop to the drain select lines DSL, the word lines WL, the source select lines SSL, and the source line SL connected to the selected memory block according to a row address RADD. For example, the row decoder 130 is connected to the voltage generator 120 through global lines and is connected to the memory blocks BLK1 to BLKj through the drain select lines DSL, the word lines WL, the source select lines SSL, and the source line SL. In an embodiment, the source line SL is not connected to the row decoder 130 and is connected to a separate source line driver (not shown).

The page buffer group 140 includes page buffers PB1 to PBn (not shown) connected to the memory blocks BLK1 to BLKj. Each of the page buffers is connected to the memory blocks BLK1 to BLKj through bit lines BL. During the read operation, the page buffers sense a current or a voltage of the bit lines, which varies according to threshold voltages of the selected memory cells and temporarily stores the sensed data in response to page buffer control signals PBSIG.

The column decoder 150 is configured such that data is transmitted between the page buffer group 140 and the input/output circuit 160 in response to a column address CADD. For example, the column decoder 150 is connected to the page buffer group 140 through column lines CL and transmits enable signals through the column lines CL. The page buffers included in the page buffer group 140 receive or output the data through data lines DL in response to the enable signals.

The input/output circuit 160 is configured to receive or output a command CMD, an address ADD, or data through input/output lines I/O. For example, the input/output circuit 160 transmits the command CMD and the address ADD received from an external controller to the control circuit 170 through the input/output lines I/O, and transmit the data received from the external controller to the page buffer group 140 through the input/output lines I/O. Alternatively, the input/output circuit 160 outputs the data received from the page buffer group 140 to the external controller through the input/output lines I/O.

The control circuit 170 outputs the operation code OPCD, the row address RADD, the page buffer control signals PBSIG, and the column address CADD in response to the command CMD and the address ADD. For example, when the command CMD input to the control circuit 170 is a command corresponding to the program operation, the control circuit 170 controls devices included in the peripheral circuit 180 to perform the program operation of a memory block selected by the address ADD. When the command CMD input to the control circuit 170 is a command corresponding to the read operation, the control circuit 170 controls the devices included in the peripheral circuit 180 to perform the read operation of the memory block selected by the address and output the read data. When the command CMD input to the control circuit 170 is a command corresponding to the erase operation, the control circuit 170 controls the devices included in the peripheral circuit 180 to perform the erase operation of the selected memory block.

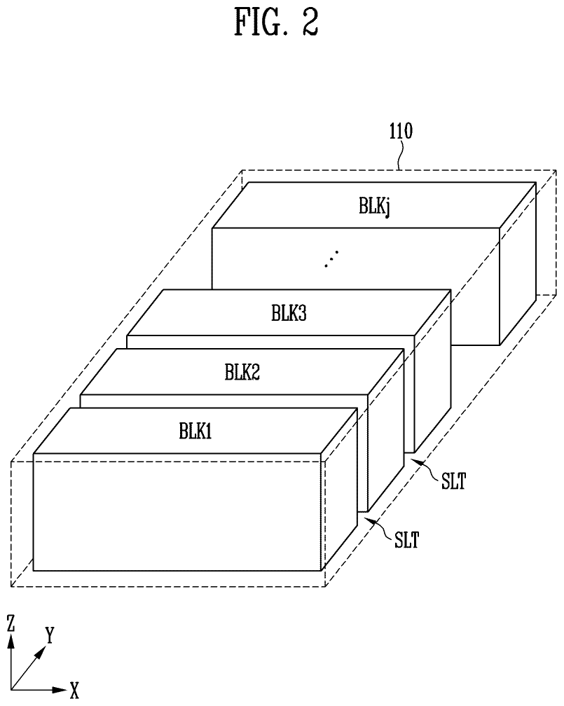

FIG. 2 is a diagram illustrating the memory cell array.

Referring to FIG. 2, the memory cell array 110 includes first memory block BLK1 to j-th memory block BLKj. Each of the memory blocks BLK1 to BLKj may be configured using same structure.

The memory blocks BLK1 to BLKj are spaced apart from each other along a Y direction. For example, the memory blocks BLK1 to BLKj are separated from each other by slits SLT. Each of the slits SLT extends along an X direction and is arranged along the Y direction.

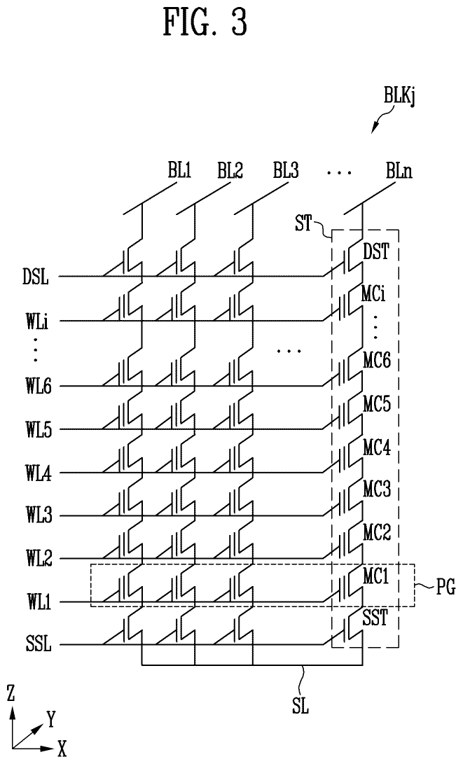

FIG. 3 is a circuit diagram illustrating the memory block.

Because the memory blocks BLK1 to BLKj shown in FIG. 2 are configured similarly to each other, the j-th memory block BLKj among the memory blocks BLK1 to BLKj is shown in FIG. 3 as an example.

Referring to FIG. 3, the j-th memory block BLKj includes strings ST connected between a first bit line BL1 to an n-th bit line BLn and the source line SL, where n is a positive integer. Because the bit lines BL1 to BLn extend along a Y direction and are arranged to be spaced apart from each other along an X direction, the strings ST extending in a Z direction are arranged to be spaced apart from each other along the X and Y directions. The strings ST arranged in the X direction are shown in FIG. 3.

When describing one string ST among the strings ST connected to the n-th bit line BLn as an example, the string ST includes a source select transistor SST, a first memory cell MC1 to an i-th memory cell MCi, and a drain select transistor DST, where i is a positive integer. Because the j-th memory block BLKj shown in FIG. 2 is a diagram illustrating a connection configuration of the memory block, the quantity of the source select transistors SST, the memory cells MC1 to MCi, and the drain select transistors DST included in the strings ST may vary according to the memory device.

Gates of the source select transistors SST included in different strings ST are connected to a source select line SSL, gates of the memory cells MC1 to MCi are connected to a first word line WL1 to an i-th word line WLi, and gates of the drain select transistors DST are connected to a drain select line DSL.

Among the memory cells MC1 to MCi, memory cells formed on the same layer or level are connected to the same word line. For example, the first memory cells MC1 included in different strings ST is commonly connected to the first word line WL1, and the i-th memory cells included in different strings ST is commonly connected to the i-th word line WLi. A group of memory cells included in different strings ST and connected to the same word line is referred to as a page PG. The program and read operations may be performed in a unit of a page PG, and the erase operation may be performed in a unit of a memory block.

FIGS. 4A and 4B are diagrams illustrating views of a first structure of a memory device according to an embodiment of the present disclosure.

Referring to FIG. 4A and FIG. 4B, a section of the memory block included in the memory device is shown. The memory block includes first material layers M1 alternatively stacked with second material layers M2, a cell plug CPL passing through the material layers M1 and M2, and a tunnel insulating layer (tunnel isolation layer) TX and a charge trap layer CT positioned between the second material layers M2 and the cell plug CPL.

The first material layers M1 may be formed including an insulating material such as an oxide layer. For example, the first material layers M1 may be a silicon oxide material. The second material layers M2 may be formed including a conductive material used as a gate line GL such as a drain select line, a word line, or a source select line. The second material layers M2 may be formed including a metal such as tungsten (W), molybdenum (Mo), cobalt (Co), and nickel (Ni), or a semiconductor material such as silicon (Si) or polysilicon (Poly-Si).

The cell plug CPL includes a blocking layer BX, a channel layer CH, and a core pillar CP extending in a Z direction and formed in a cylindrical shape.

The blocking layer BX includes a first blocking layer B1, a second blocking layers B2, and a third blocking layer B3. Among the blocking layers B1 to B3, the first blocking layer B1 is positioned outermost radially, and the second and third blocking layers B2 and B3 are sequentially positioned radially inward of the first blocking layer B1 toward the channel layer CH. The third blocking layer B3 may be formed in a cylindrical shape. The second blocking layer B2 surrounds the third blocking layer B3. The first blocking layer B1 surrounds the second blocking layer B2. The first blocking layer B1 and the third blocking layer B3 may be formed including an oxide material, and the second blocking layer B2 may be formed including a nitride material. Alternatively, the first blocking layer B1 and the third blocking layer B3 may be formed including a high dielectric material (high-K), and the second blocking layer B2 may be formed including a low dielectric material (low-K). The channel layer CH surrounds the core pillar CP and may be formed including polysilicon. The core pillar CP may be formed in a cylindrical shape and may be formed including an insulating material or a conductive material.

The tunnel insulating layer TX and the charge trap layer CT are positioned in the X direction between the first material layers M1. The tunnel insulating layer TX is positioned between the second material layer M2 and the charge trap layer CT and may be formed including an insulating material. The tunnel insulating layer TX may be formed including a silicon oxide material. The charge trap layer CT is positioned between the tunnel insulating layer TX and the cell plug CPL and may be formed including a material that traps an electron. For example, the charge trap layer CT may be formed including a nitride material. The charge trap layer CT may be formed including at least one of silicon nitride SiN and silicon-oxynitride SiON.

The cell plug CPL may have a first width W1 or diameter regardless of a position. A width W1 or diameter of an inner wall of the first material layer M1 surrounding the cell plug CPL is the same as a width W1 or diameter of an inner wall of the charge trap layer CT. Because the charge trap layer CT and the tunnel insulating layer TX surround a surface of the cell plug CPL, a width or a diameter of a wall surrounding an outer surface of the tunnel insulating layer TX has a second width W2 or diameter larger than the first width W1 or diameter. When a structure surrounded by the second material layer M2 is a memory cell, the memory cell has the second width W2.

The charge trap layer CT included in the memory cell traps electrons during a program operation and discharges or releases the electrons during an erase operation. In an embodiment, because the tunnel insulating layer TX is positioned between the gate line GL and the charge trap layer CT, and the blocking layer BX is positioned between the charge trap layer CT and the channel layer CH, during the program operation, the electrons of the gate line GL pass through the tunnel insulating layer TX and are trapped in the charge trap layer CT. As described, the program voltage applied to the selected word line is a negative voltage lower than 0V such that the electrons move from the gate line GL to the charge trap layer CT during the program operation. The erase voltage applied to the word line is a positive voltage higher than 0V such that the electrons may move from the charge trap layer CT to the gate line GL during the erase operation. Because the electrons are trapped in the charge trap layer CT of a programmed memory cell, the read voltage applied to the selected word line during the read operation is a positive voltage higher than 0V.

According to the first structure of the present disclosure, because the first material layers M1 formed including an insulating material are positioned between the charge trap layers CT stacked in the Z direction, interference between memory cells located nearest to each other in the Z direction may be reduced. In addition, because the charge trap layers CT adjacent to each other in the Z direction are separated from each other, each of the charge trap layers CT is in a floating state. As a result, when the electrons are trapped in the charge trap layer CT, the electrons trapped in the charge trap layer CT are maintained until the erase operation is performed, and a data retention characteristic of the memory device may be improved.

A method of manufacturing the memory device is described in detail.

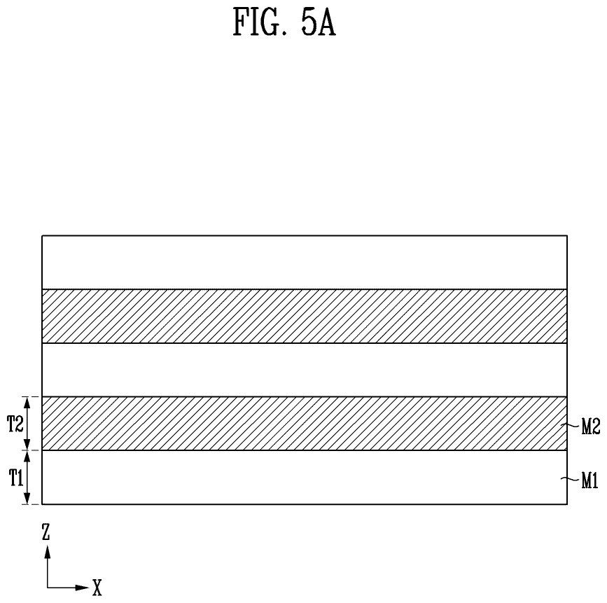

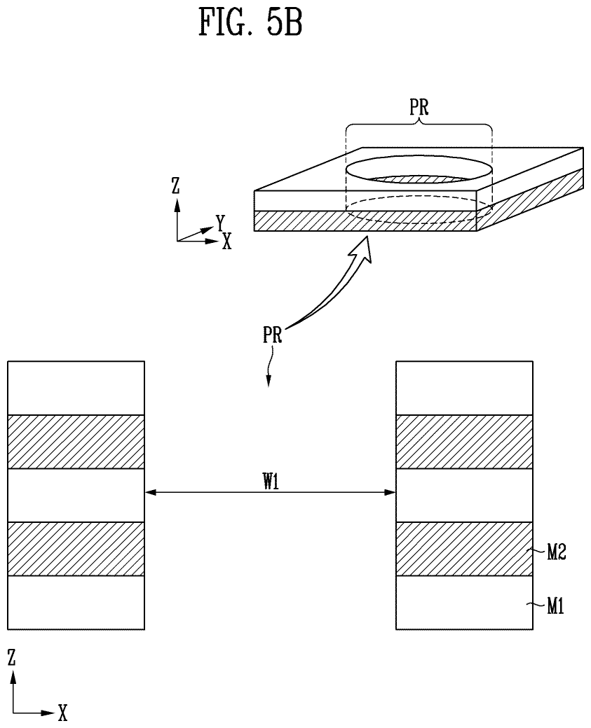

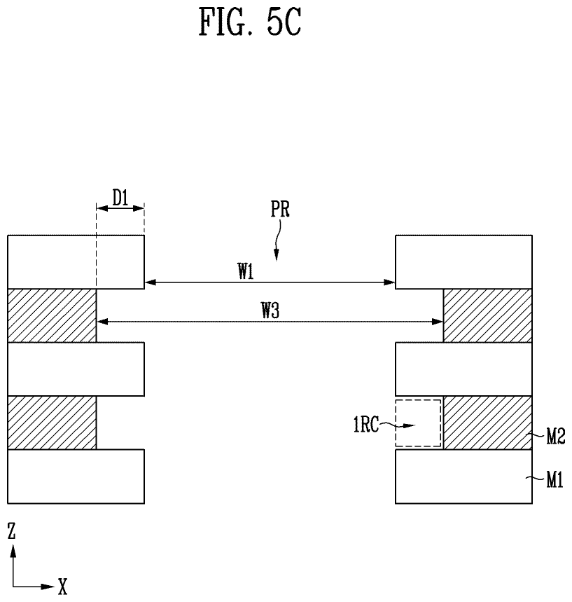

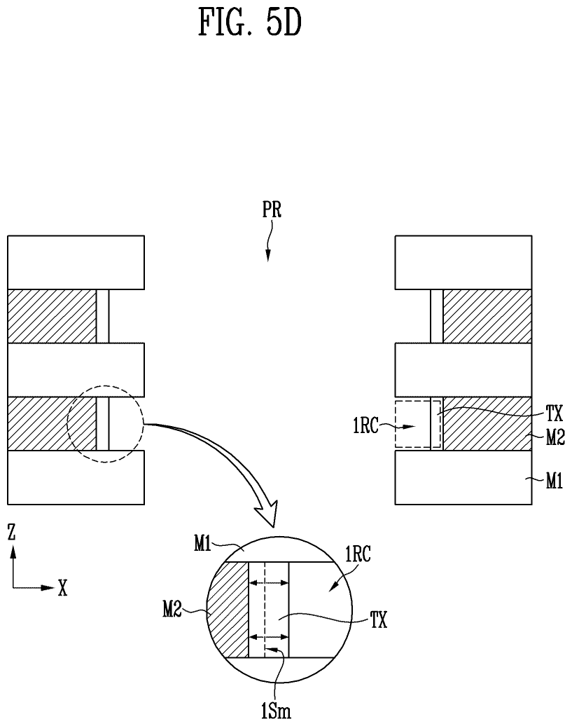

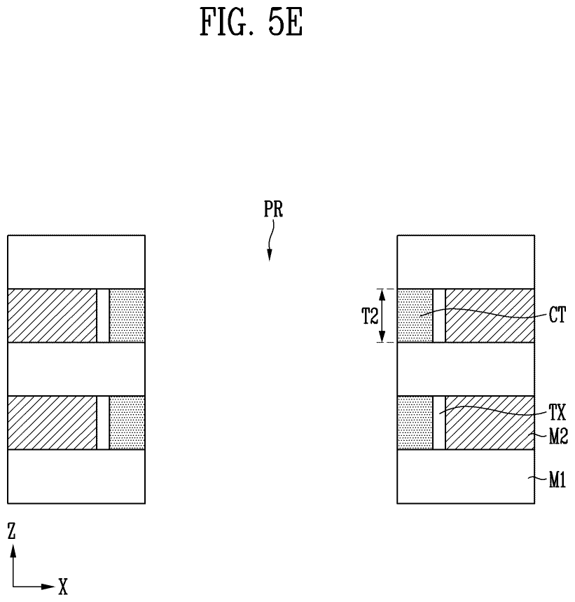

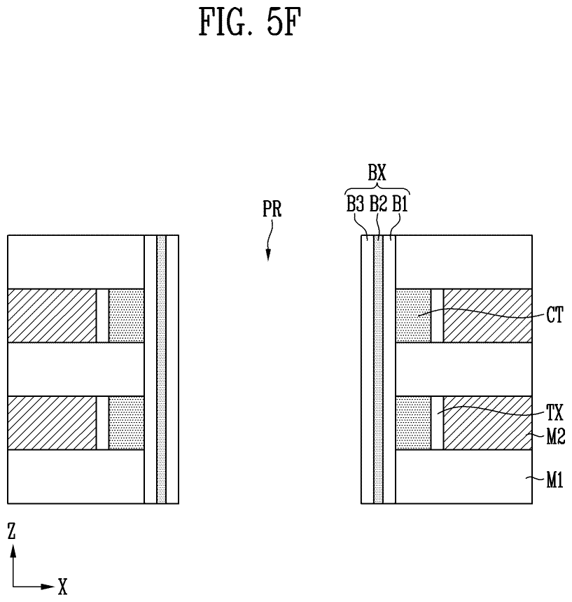

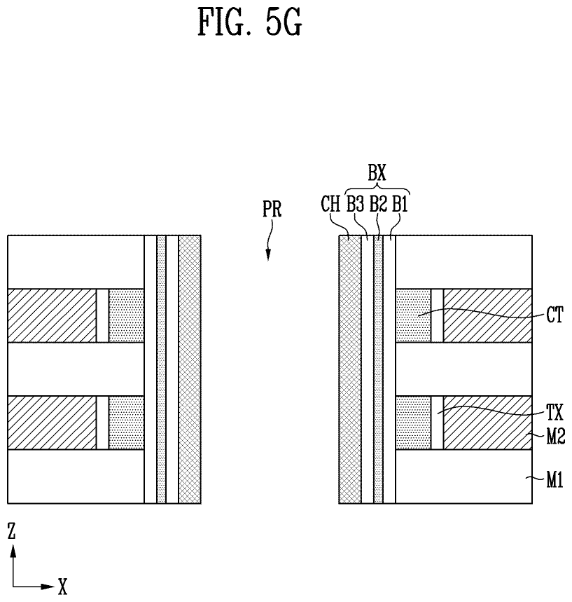

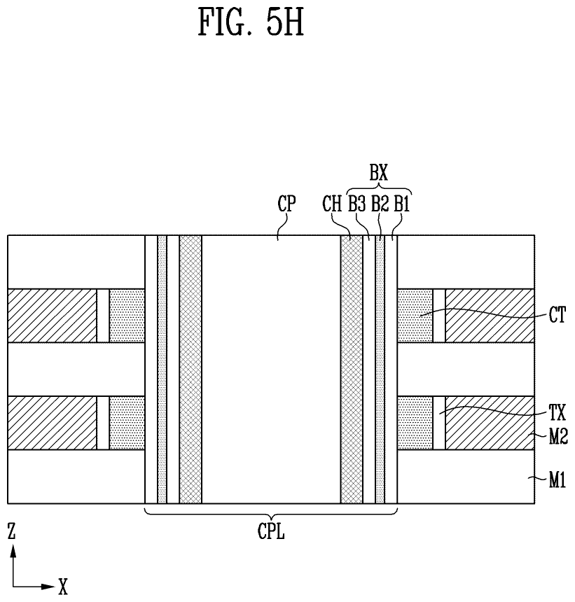

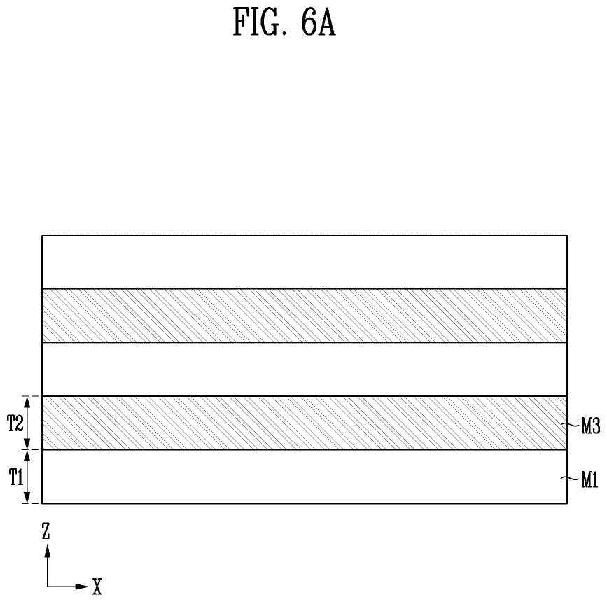

FIG. 5A to FIG. 5H are diagrams illustrating views of a first structure of a memory device formed utilizing a first method of manufacturing the first structure.

Referring to FIG. 5A, first material layers M1 are alternately stacked with second material layers M2 along the Z direction on a lower structure (not shown). The lower structure may be a substrate or a peripheral circuit, and various other structures may be included. The first material layers M1 are formed including an insulating material such as an oxide layer. For example, the first material layers M1 may be a silicon oxide material. The second material layers M2 are formed including a conductive material to be used as gate lines GL such as the drain select line, the word line, and the source select line. For example, the second material layers M2 may be formed including a metal material such as tungsten (W), molybdenum (Mo), cobalt (Co), and nickel (Ni), or a semiconductor material such as silicon (Si) or polysilicon (Poly-Si). Each of the first material layers M1 is formed having a first thickness T1, and each of the second material layers M2 is formed having a second thickness T2. The second thickness T2 may be equal to or less than the first thickness T1.

Referring to FIG. 5B, an etching process that forms an opening PR passing through the material layers M1 and M2 is performed. The opening PR may have a circular or elliptical shape in the XY plane.

To form the opening PR in a direction perpendicular to the material layers M1 and M2, the etching process is performed, for example, using a dry etching method. For example, an anisotropic dry etching process may be performed. The opening PR is formed having the first width W1 or diameter. For example, a space between the first material layers M1 is an opening PR at the first width W1 or diameter, and the opening PR is formed such that a space between the second material layers M2 has the first width W1. When the opening PR is formed, a surface of each of the material layers M1 and M2 is exposed through the opening PR.

Referring to FIG. 5C, an etching process is performed that removes a section of the second material layers M2 exposed through the opening PR. To selectively remove a section of the second material layers M2, an etchant having a higher selectivity for the second material layers M2 than the selectivity of the first material layers M1 is used. Regions where a sections of the second material layers M2 are removed are referred to as first recesses 1RC. For example, the second material layers M2 are removed by a first distance D1. As a result, a width W3 or diameter/distance between the second material layers M2 where the first recesses 1RC are formed is larger than the first width W1 or diameter. The third width W3 is (2×D1)+W1. The third width W3 may be equal to or less than the second width W2 of FIG. 4A.

Referring to FIG. 5D, the tunnel insulating layers TX are selectively formed on a surface of the second material layers M2 exposed through the first recesses 1RC. The tunnel insulating layer TX may be formed using an oxidation process. For example, the second material layers M2 are oxidized to form a film, having a surface 1Sm, on the second material layers M2 using the oxidation process, and an oxide layer is formed on the surface 1Sm of the film of the second material layers M2. The tunnel insulating layer TX is formed within the first recesses 1RC and on the film formed by oxidizing a section of the second material layers M2. As described with reference to FIG. 5C, the third width W3 is equal to or less than the second width W2 of FIG. 4A.

Referring to FIG. 5E, the charge trap layers CT is formed in the remaining spaces of the first recesses 1RC of FIG. 5D where the tunnel insulating layers TX are formed. The charge trap layers CT may be formed including polysilicon. For example, after the polysilicon for the charge trap layer CT is formed within the opening PR to fill the first recesses 1RC, the polysilicon may form on the surfaces of the first material layers M1. An etching process may be performed to remove the polysilicon formed on the surfaces of the first material layers M1 as the polysilicon filled in the first recesses 1RC remains. Because the charge trap layers CT are formed in a region where the second material layers M2 are positioned, each of the charge trap layers CT is formed at the second thickness T2.

Referring to FIG. 5F, the blocking layer BX is formed along a surface of the charge trap layers CT and the first material layers M1 exposed in the opening PR. The blocking layer BX includes the blocking layers B1 to B3. For example, the first blocking layer B1 is formed along a surface of the first material layers M1 and the charge trap layers CT exposed through the opening PR. The second blocking layer B2 is formed along a surface of the first blocking layer B1 exposed through the opening PR. The third blocking layer B3 is formed along a surface of the second blocking layer B2 exposed through the opening PR. Each of the blocking layers B1, B2, and B3 may be formed with the same thickness in the X direction. When the opening PR is formed in a circular or elliptical shape in the XY plane, the blocking layer BX is formed in a cylindrical shape.

Referring to FIG. 5G, the channel layer CH is formed along an innermost surface of the blocking layer BX exposed through the opening PR. For example, the channel layer CH is formed along a surface of the third blocking layer B3. Because the blocking layer BX is formed in a cylindrical shape, the channel layer CH is formed in a cylindrical shape. The channel layer CH may be formed including polysilicon.

Referring to FIG. 5H, the core pillar CP is formed in a region surrounded by the channel layer CH. The core pillar CP may include an insulating material or a conductive material and is filled into a region surrounded by the channel layer CH. Accordingly, the cell plug CPL including the blocking layer BX, the channel layer CH, and the core pillar CP are formed.

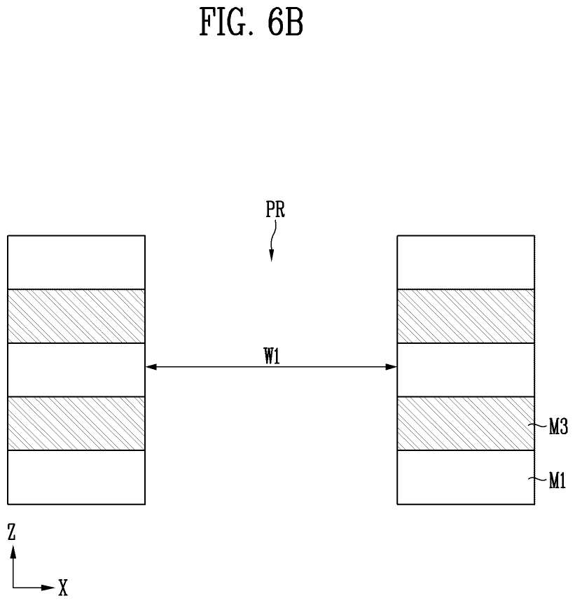

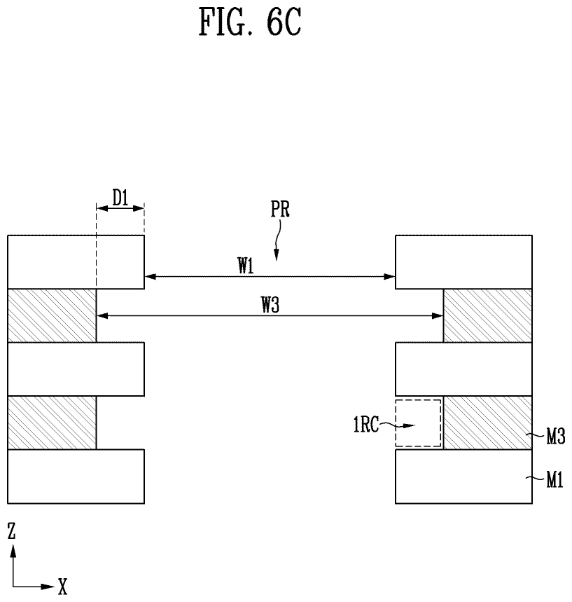

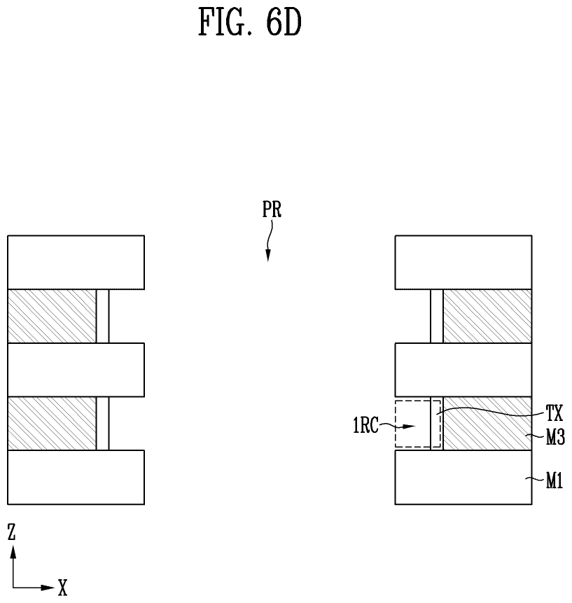

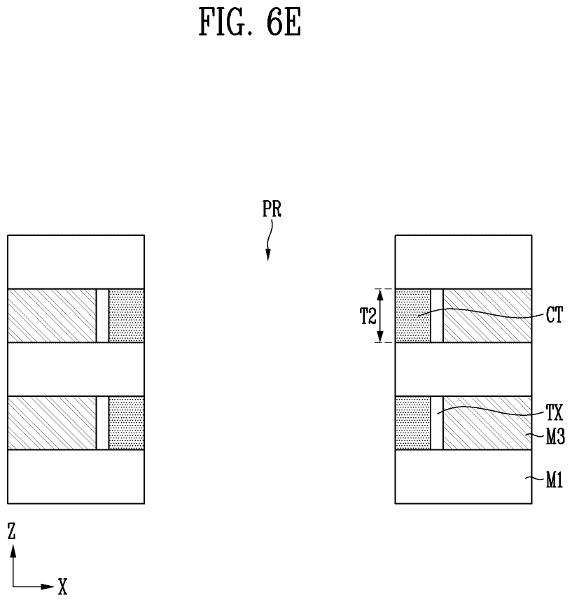

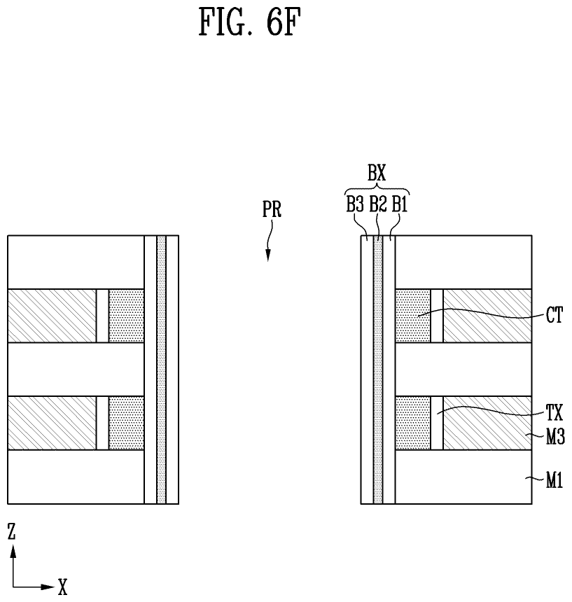

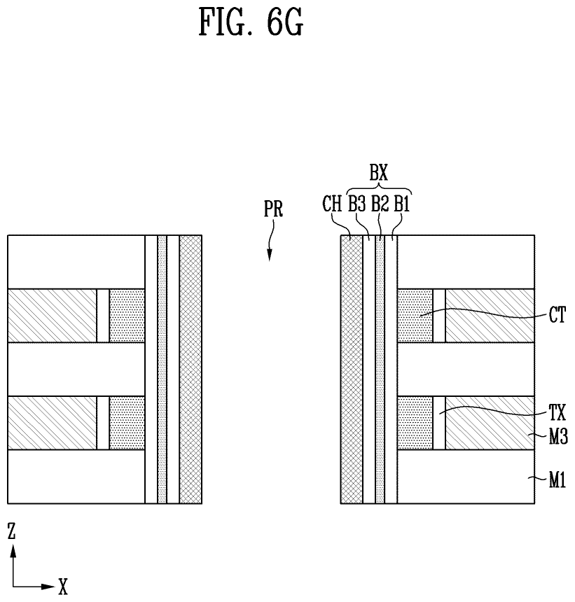

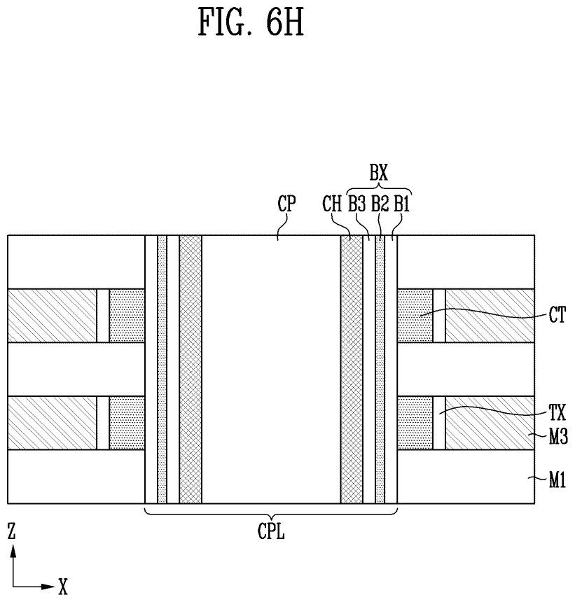

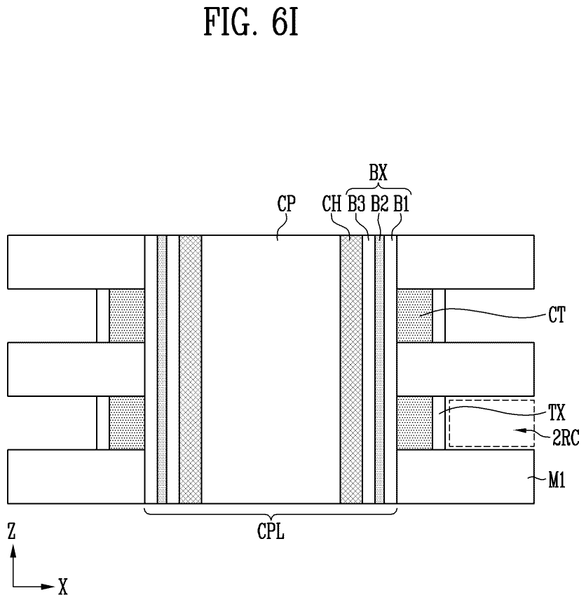

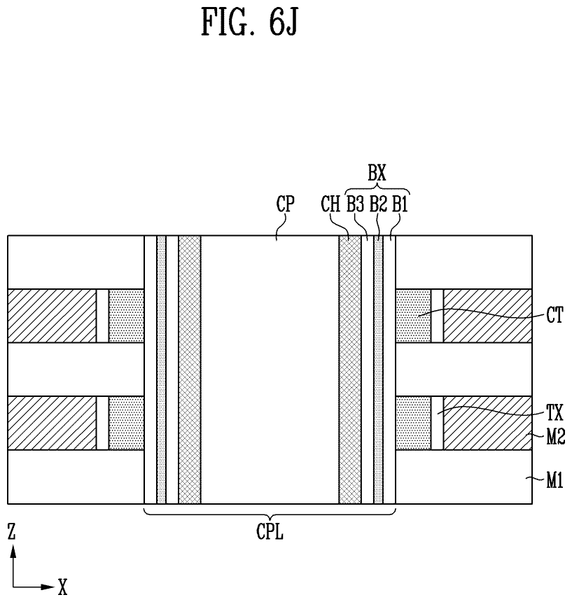

FIG. 6A to FIG. 6J are diagrams illustrating views of a first structure of a memory device formed utilizing a second method of manufacturing the first structure.

During the second method of manufacturing the first structure, a third material layer M3 that is a material different than the second material layer M2 is formed instead of the second material layer M2 of FIG. 5A. The second material layer M2 is filled into a region where the third material layer M3 is removed in a subsequent process. The second method of manufacturing the first structure is described in detail.

Referring to FIG. 6A, the first material layers M1 are alternately stacked with the third material layers M3 along the Z direction on the lower structure (not shown). The lower substructure may be a substrate or a peripheral circuit, and various structures may be included. The first material layers M1 may be formed including an insulating material such as an oxide layer. For example, the first material layers M1 may be a silicon oxide material. The third material layers M3 may be formed including a material having an etch selectivity different from the etch selectivity of the first material layers M1 for use as a sacrificial layer. The third material layers M3 may be formed including a nitride material. The third material layers M3 may be formed including a silicon nitride material. Each of the first material layers M1 is formed having the first thickness T1, and each of the third material layers M3 is formed having the second thickness T2. The second thickness T2 is equal to or less than the first thickness T1.

Referring to FIG. 6B, an etching process that forms an opening PR passing through the material layers M1 and M3 is performed. The opening PR may have a circular or elliptical shape in the XY plane.

To form the opening PR in a direction perpendicular to the material layers M1 and M3, an etching process is performed, for example, using a dry etching method. For example, an anisotropic dry etching process may be performed. The opening PR is formed having the first width W1 or diameter. For example, a space between the first material layers M1 is an opening PR at the first width W1 or diameter, and the opening PR is formed such that a space between the third material layers M3 has the first width W1. When the opening PR is formed, a surface of each of the material layers M1 and M3 is exposed through the opening PR.

Referring to FIG. 6C, an etching process is performed that removes a section of the third material layers M3 exposed through the opening PR. To selectively remove a section of the third material layers M3, an etchant having a higher selectivity for the third material layers M3 than the selectivity of the first material layers M1 is used. Regions where a section of the third material layers M3 is removed are referred to as first recesses 1RC. For example, the third material layers M3 are removed by a first distance D1. As a result, a width W3 or diameter/distance between the third material layers M3 where the first recesses 1RC are formed is larger than the first width W1 or diameter. The third width W3 may be equal to or less than the second width W2 of FIG. 4A.

Referring to FIG. 6D, the tunnel insulating layers TX are selectively formed on a surface of the third material layers M3 exposed through the first recesses 1RC. The tunnel insulating layer TX may be formed using an oxidation process. The tunnel insulating layer TX is formed within the first recesses 1RC from a section of the third material layers M3 by the oxidation process. As described with reference to FIG. 6C, the third width W3 is equal to or less than the second width W2 of FIG. 4A.

Referring to FIG. 6E, the charge trap layers CT is formed in the remaining space of the first recesses 1RC of FIG. 6D where the tunnel insulating layers TX are formed. The charge trap layers CT may be formed including polysilicon. For example, after the polysilicon for the charge trap layer CT is formed within the opening PR to fill the first recesses 1RC, polysilicon may form on the surfaces of the first material layers M1. An etching process may be performed to remove the polysilicon formed on the surfaces of the first material layers M1 as the polysilicon filled in the first recesses 1RC remains. Because the charge trap layers CT are formed in a region where the third material layers M3 are positioned, each of the charge trap layers CT has the second thickness T2.

Referring to FIG. 6F, the blocking layer BX is formed along a surface of the opening PR where a surface of the charge trap layers CT and the first material layers M1 is exposed. The blocking layer BX includes the blocking layers B1 to B3. For example, the first blocking layer B1 is formed along a surface of the first material layers M1 and the charge trap layers CT exposed through the opening PR. The second blocking layer B2 is formed along a surface of the first blocking layer B1 exposed through the opening PR. The third blocking layer B3 is formed along a surface of the second blocking layer B2 exposed through the opening PR. When the opening PR is formed in a circular or elliptical shape in the XY plane, the blocking layer BX is formed in a cylindrical shape.

Referring to FIG. 6G, the channel layer CH is formed along a surface of the blocking layer BX exposed through the opening PR. For example, the channel layer CH is formed along a surface of the third blocking layer B3 of the blocking layer BX. Because the blocking layer BX is formed in a cylindrical shape, the channel layer CH is formed in a cylindrical shape. The channel layer CH may be formed including polysilicon.

Referring to FIG. 6H, the core pillar CP is formed in a region surrounded by the channel layer CH. The core pillar CP may include an insulating material or a conductive material and is filled in a region surrounded by the channel layer CH. Accordingly, the cell plug CPL including the blocking layer BX, the channel layer CH, and the core pillar CP are formed.

Referring to FIG. 6I, as shown in FIG. 2, a trench is be formed in a slit region SLT that divides the memory blocks, and an etching process is performed that removes the third material layers M3 exposed through the trench. Regions where the third material layers M3 are removed are referred to as second recesses 2RC. Areas of the first material layers M1 and areas of the tunnel insulating layers TX are exposed through the second recesses 2RC.

Referring to FIG. 6J, the second material layers M2 are formed in the second recesses 2RC of FIG. 6I. For example, the second material layers M2 fill the second recesses 2RC through the slit region SLT described with reference to FIG. 6I and FIG. 2.

FIG. 7 is a diagram illustrating a second structure of a memory device according to an embodiment of the present disclosure.

Referring to FIG. 7, in the second structure of the present disclosure, the charge trap layer CT includes a protrusion PT. The protrusion PT includes a surface 2Sm that protrudes or extends from the charge trap layer CT in a direction toward a central axis AX of the cell plug CPL. The surface 2Sm of the protrusion PT may be a convex curved surface. A width between closest points of the surfaces 2Sm of the charge trap layers CT on a same level in the Z direction through the cell plug CPL is a fourth width W4 or diameter that is narrower than the first width W1 or diameter.

Due to being formed on the protrusion PT, a section of the blocking layer BX and a section of the channel layer CH also have a convex shape. For example, because the first blocking layer B1 is formed first among the blocking layers B1 to B3 included in the blocking layer BX, a sections of the first blocking layer B1 formed along a surface of the first material layers M1 and the charge trap layers CT has a convex shape due to the protrusions PT.

An outer surface of the channel layer CH is uneven and includes sections having a concave shape due to formation on the third blocking layer B3 that has an uneven surface. An interface or boundary between the channel layer CH and the core pillar CP is convex in areas corresponding to the protrusions PT. The channel layer CH is thicker than the third blocking layer B3, and an inner surface of the channel layer CH is flat and is formed substantially in a straight line in the Z direction.

When the charge trap layers CT include the protrusion PTs, because a volume of the charge trap layer CT increases, the electrons are more stably trapped during the program operation. Because the area where the charge trap layer CT contacts the blocking layer BX and the area where the blocking layer BX contacts the channel layer CH are larger in the example of FIG. 7 than in the example of FIG. 4A, a coupling ratio between the charge trap layer CT and the channel layer CH may be improved.

Components except for the protrusion PT of the charge trap layer CT and the blocking layer BX described with reference to FIG. 7 are similar to components described with reference to FIG. 4A.

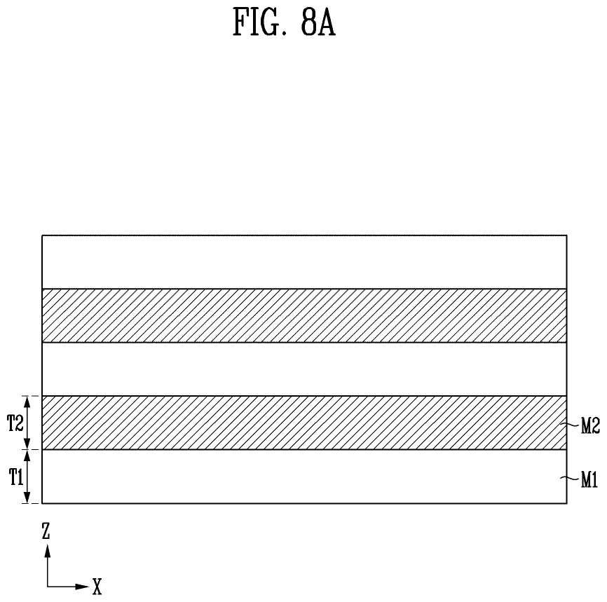

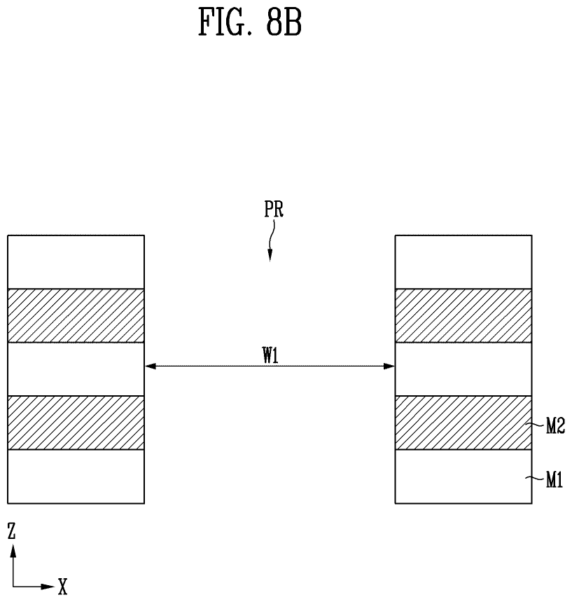

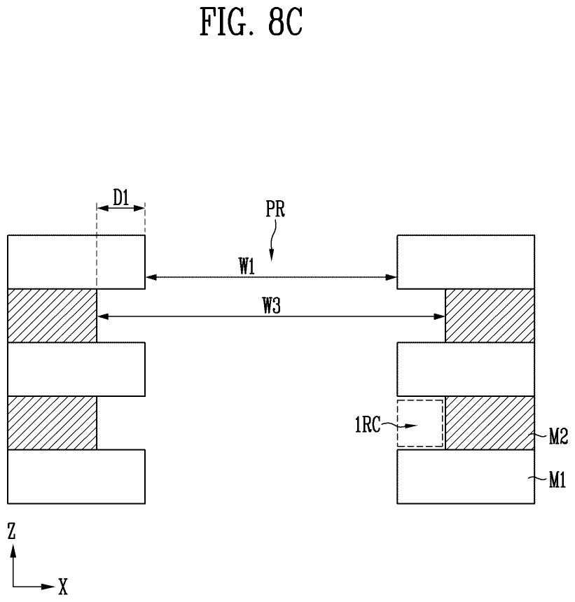

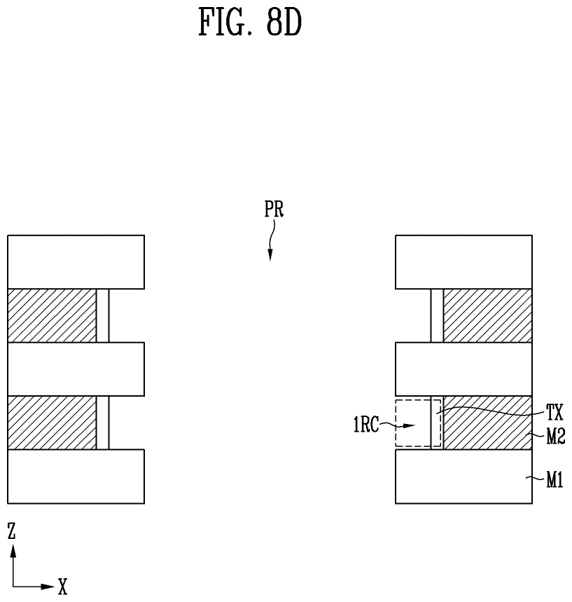

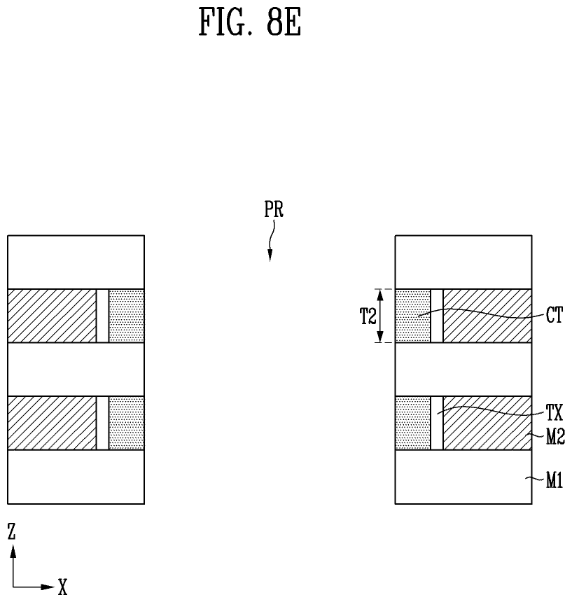

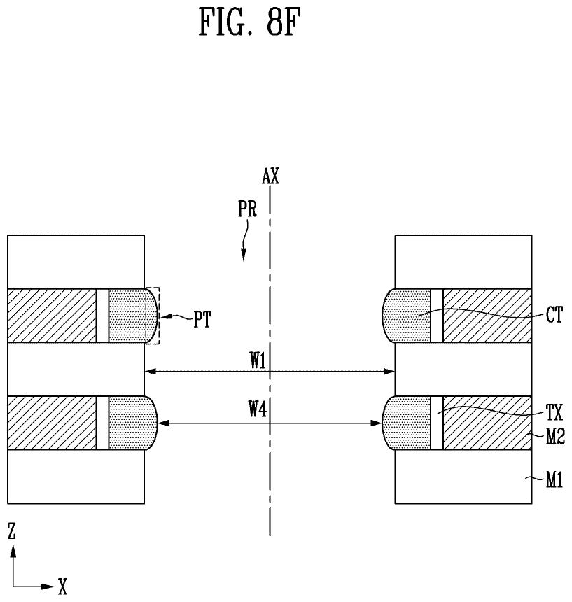

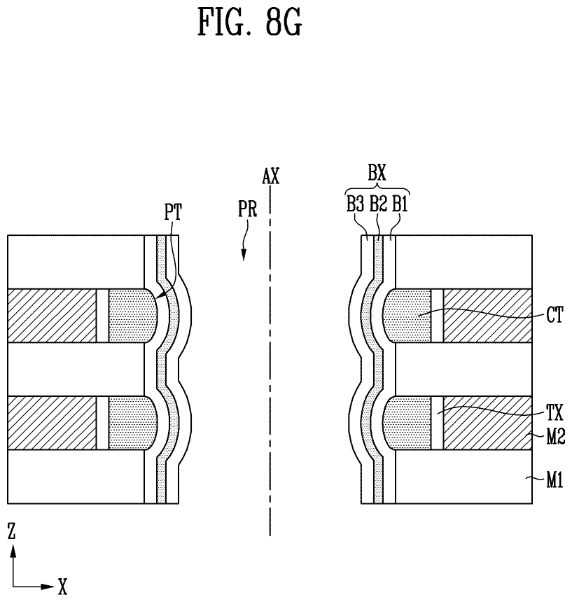

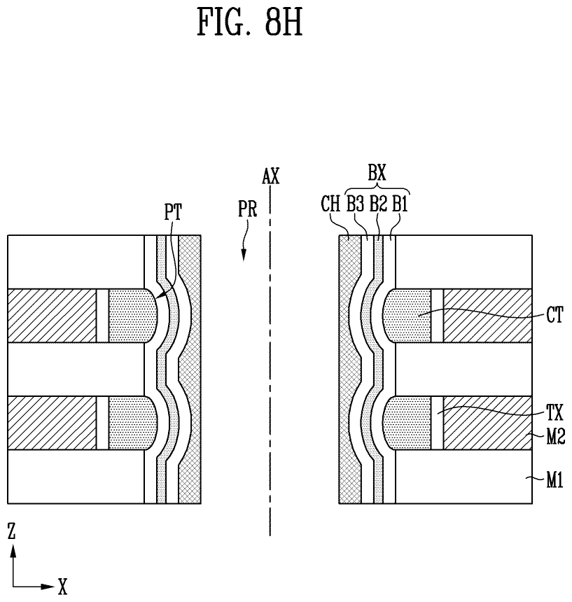

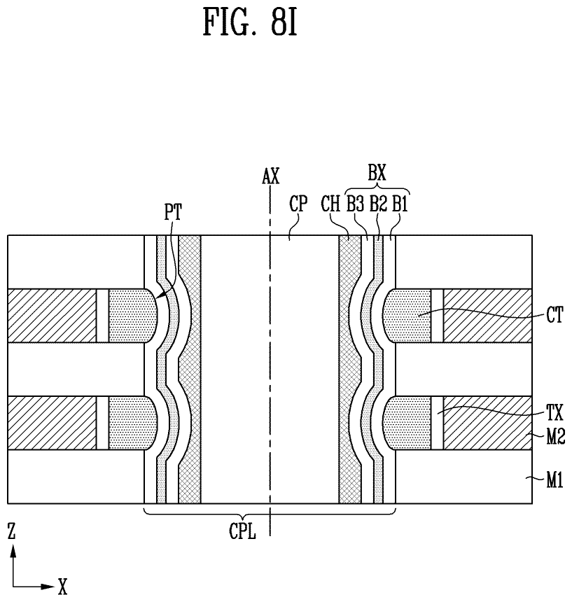

FIG. 8A to FIG. 8I are diagrams illustrating views of a second structure of a memory device formed utilizing a first method of manufacturing the second structure.

Referring to FIG. 8A, first material layers M1 are alternately stacked with second material layers M2 along the Z direction on a lower structure (not shown). The lower structure may be a substrate or a peripheral circuit, and various other structures may be included. The first material layers M1 are formed including an insulating material such as an oxide layer. For example, the first material layers M1 may be a silicon oxide material. The second material layers M2 are formed including a conductive material to be used as a gate line GL such as the drain select line, the word line, or the source select line. The second material layers M2 may be formed including a metal such as tungsten (W), molybdenum (Mo), cobalt (Co), and nickel (Ni), or a semiconductor material such as silicon (Si) or polysilicon (Poly-Si). Each of the first material layers M1 is formed having a first thickness T1, and each of the second material layers M2 is formed having a second thickness T2. The second thickness T2 may be equal to or less than the first thickness T1.

Referring to FIG. 8B, an etching process that forms an opening PR passing through the material layers M1 and M2 is performed. The opening PR may have a circular or elliptical shape in the XY plane.

To form the opening PR in a direction perpendicular to the material layers M1 and M2, the etching process is performed, for example, using a dry etching method. For example, an anisotropic dry etching process may be performed. The opening PR is formed having the first width W1 or diameter. For example, a space between the first material layers M1 is an opening PR at the first width W1 or diameter, and the opening PR is formed such that a space between the second material layers M2 has the first width W1. When the opening PR is formed, a surface of each of the material layers M1 and M2 is exposed through the opening PR.

Referring to FIG. 8C, an etching process is performed that removes a section of the second material layers M2 exposed through the opening PR. To selectively remove a section of the second material layers M2, an etchant having a higher selectivity for the second material layers M2 than that the selectivity the first material layers M1 is used. Regions where a sections of the second material layers M2 are removed are removed are referred to as first recesses 1RC. For example, the second material layers M2 are removed by a first distance D1. As a result, a width W3 or diameter/distance between the second material layers M2 where the first recesses 1RC are formed is larger than the first width W1 or diameter. The third width W3 is (2×D1)+W1. The third width W3 may be equal to or less than the second width W2 of FIG. 4A.

Referring to FIG. 8D, the tunnel insulating layers TX are selectively formed on a surface of the second material layers M2 exposed through the first recesses 1RC. The tunnel insulating layer TX may be formed using an oxidation process.

Referring to FIG. 8E, the charge trap layers CT is formed in the remaining spaces of the first recesses 1RC of FIG. 8D where the tunnel insulating layers TX are formed. The charge trap layers CT may be formed including polysilicon. For example, after the polysilicon for the charge trap layer CT is formed within the opening PR to fill the first recesses 1RC, polysilicon may form on the surfaces of the first material layers M1. An etching process may be performed to remove the polysilicon formed on the surfaces of the first material layers M1 as the polysilicon filled in the first recesses 1RC remains. Because the charge trap layers CT are formed in a region where the second material layers M2 are positioned, each of the charge trap layers CT is formed at the second thickness T2.

Referring to FIG. 8F, the protrusions PT are selectively formed on surfaces of the charge trap layers CT exposed through the opening PR. For example, forming the protrusions PT may be performed utilizing an in-situ method after forming the charge trap layers CT. The protrusions PT may be formed utilizing a method in which the protrusions PT are grown from respective charge trap layers CT. Because the area at a center of the protrusion PT in the Z direction is greater than an area at a top edge and a bottom edge of the protrusion PT of the charge trap layer CT exposed through the opening PR, the protrusion PT grows faster at the center of the charge trap layers CT. As a result, the protrusions PT are formed having a curved surface. Because the protrusions PT extend in the direction of the central axis AX of the opening PR, a width between the protrusions PR positioned on the same layer in the Z direction is the fourth width W4 that is narrower than the first width W1.

Referring to FIG. 8G, the blocking layer BX is formed along a surface of the protrusions PT and the first material layers M1 exposed in the opening PR. The blocking layer BX includes the blocking layers B1 to B3. For example, the first blocking layer B1 is formed along a surface of the first material layers M1 and the protrusions PT are exposed through the opening PR. The second blocking layer B2 is formed along a surface of the first blocking layer B1 exposed through the opening PR. The third blocking layer B3 is formed along a surface of the second blocking layer B2 exposed through the opening PR. Each of the blocking layers B1, B2, and B3 may be formed with the same thickness in the X direction. Because the blocking layers B1 to B3 are formed along a surface of the protrusions PT and the first material layers M1, the blocking layers B1 to B3 formed on the protrusions PT have a convex curved surface. The blocking layer BX may be formed in a cylindrical shape with an uneven side surface.

Referring to FIG. 8H, the channel layer CH is formed along an innermost surface of the blocking layer BX exposed through the opening PR. For example, the channel layer CH is formed along a surface of the third blocking layer B3. Because the blocking layer BX is formed in a cylindrical shape, the channel layer CH is also be formed in a cylindrical shape. In this example, the innermost surface of the channel layer CH is cylindrical and straight in the Z direction, whereas the outermost surface of the channel layer CH is uneven and follows the contours of the third blocking layer B3, including flat sections alternating with concave sections that mate with convex sections of the third blocking layer B3. The channel layer CH may be formed including polysilicon. The channel layer CH between the protrusions PT is formed to be thicker than each of the blocking layers B1 to B3 in the X direction.

Referring to FIG. 8I, the core pillar CP is formed in a region surrounded by the channel layer CH. The core pillar CP may include an insulating material or a conductive material and is filled into a region surrounded by the channel layer CH. Accordingly, the cell plug CPL including the blocking layer BX, the channel layer CH, and the core pillar CP are formed.

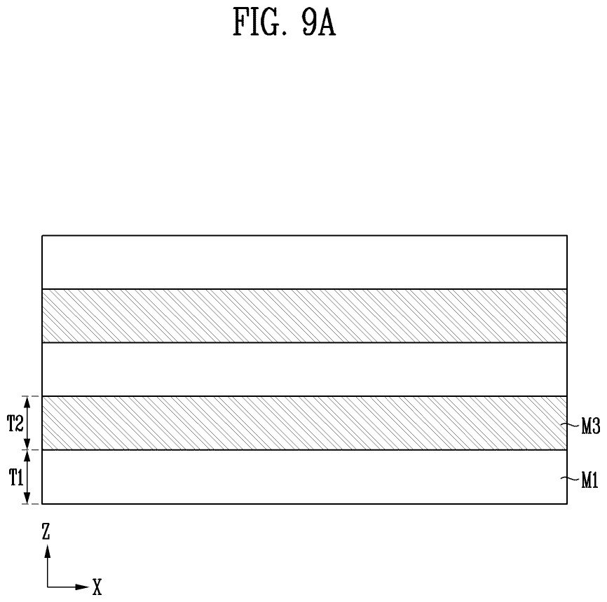

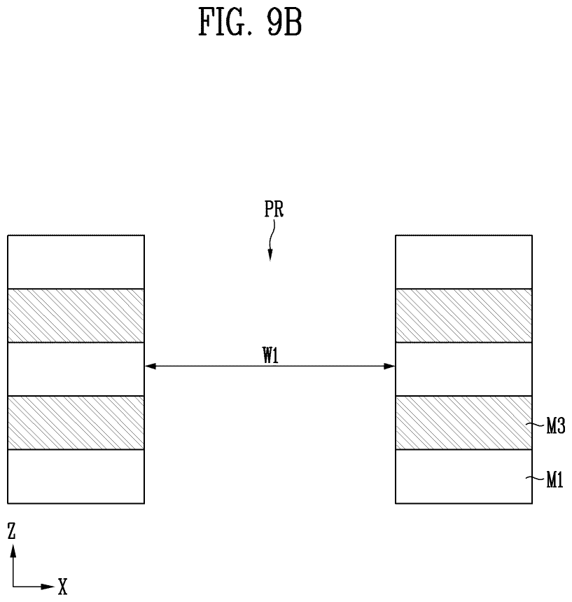

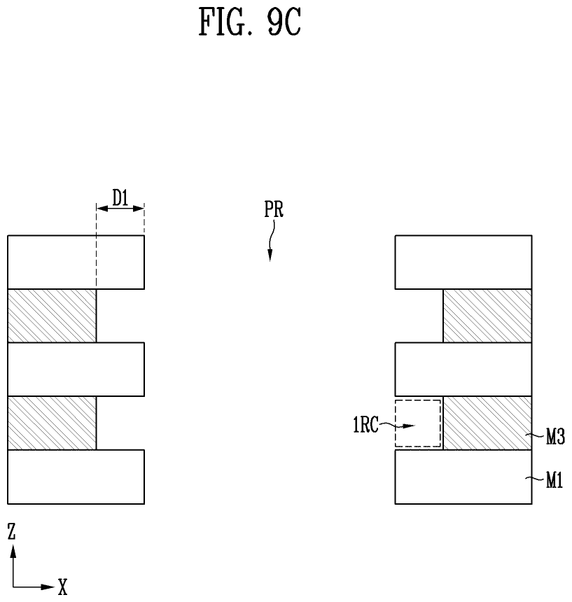

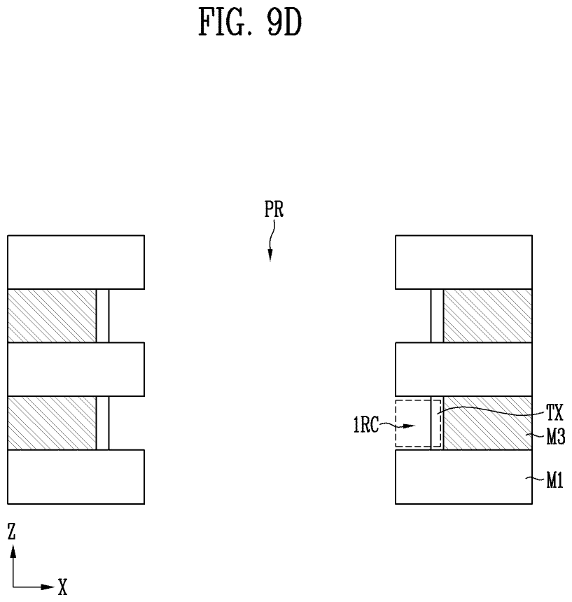

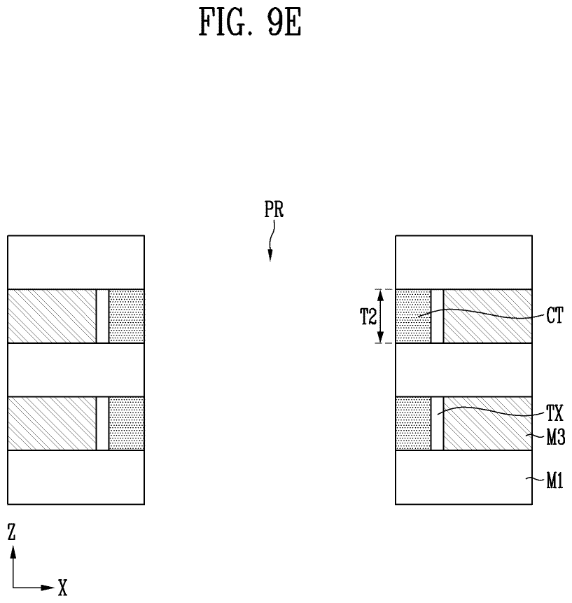

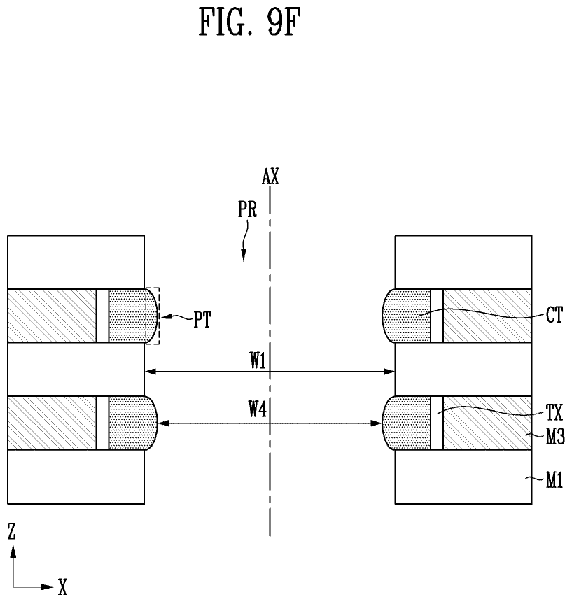

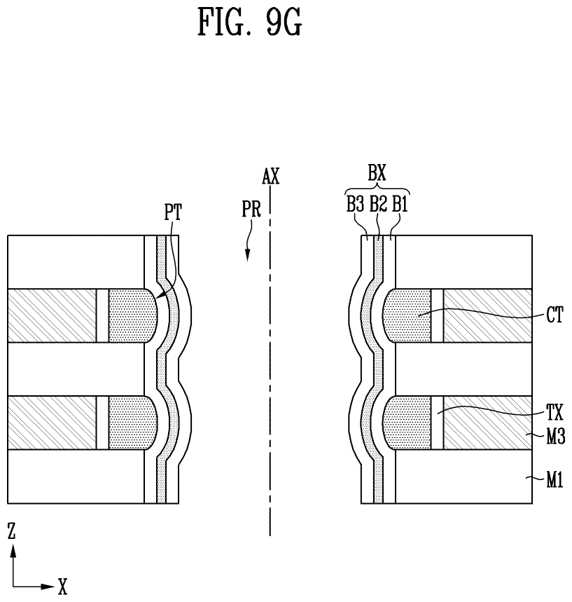

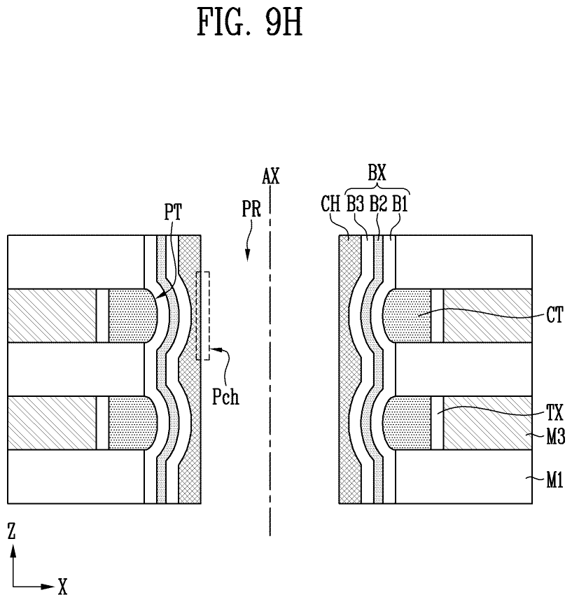

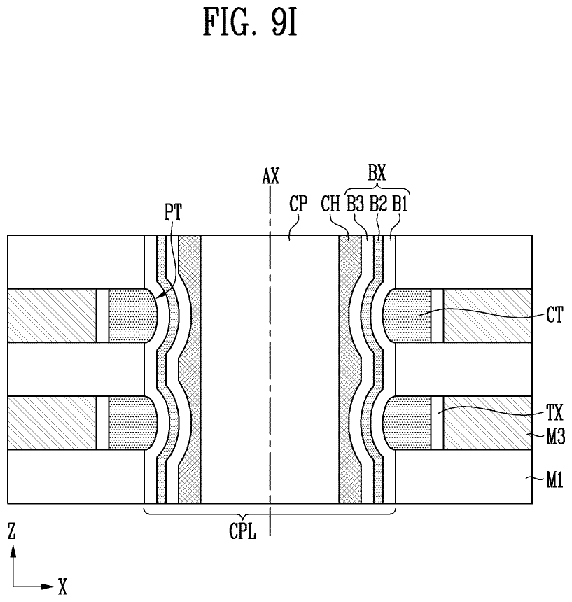

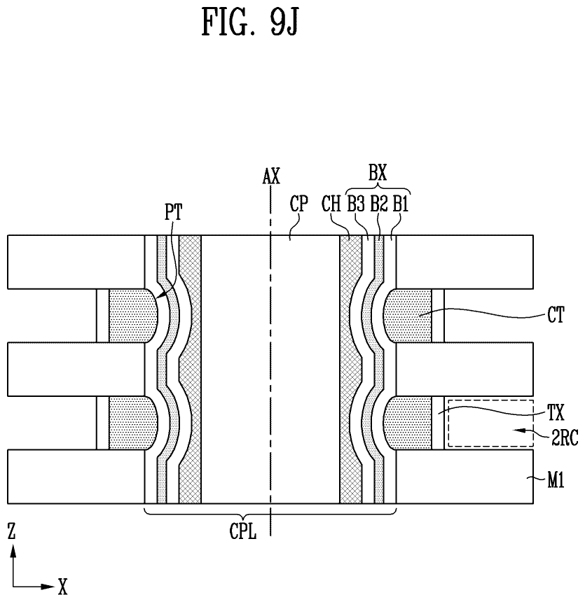

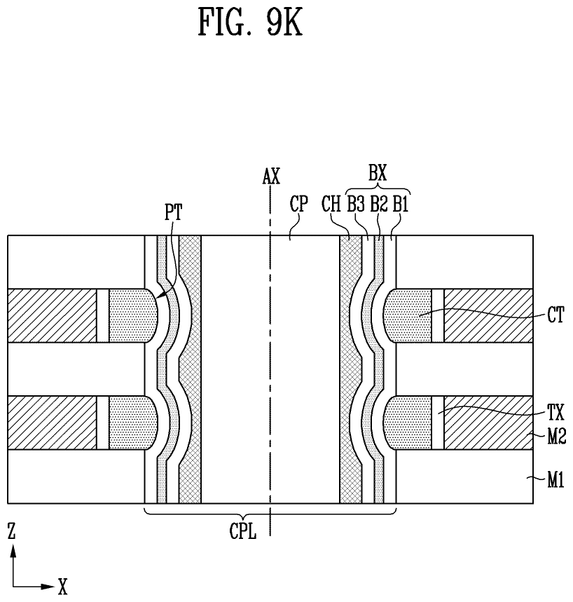

FIG. 9A to FIG. 9K are diagrams illustrating views of a second structure of a memory device formed utilizing a second method of manufacturing the second structure.

During the second method of manufacturing the second structure, a third material layer M3 that is a material different than the second material layer M2 is formed instead of the second material layer M2 of FIG. 8A. The second material layer M2 is filled into a region where the third material layer M3 is removed in a subsequent process. The second method of manufacturing the second structure is described in detail.

Referring to FIG. 9A, the first material layers M1 are alternately stacked with the third material layers M3 along the Z direction on the lower structure (not shown). The lower substructure may be a substrate or a peripheral circuit, and various structures may be included. The first material layers M1 may be formed including an insulating material such as an oxide layer. For example, the first material layers M1 may be a silicon oxide material. The third material layers M3 may be formed including a material having an etch selectivity different from the etch selectivity of the first material layers M1 for use as a sacrificial layer. The third material layers M3 may be formed including a nitride material. The third material layers M3 may be formed including a silicon nitride material. Each of the first material layers M1 is formed having the first thickness T1, and each of the third material layers M3 is formed having the second thickness T2. The second thickness T2 is equal to or less than the first thickness T1.

Referring to FIG. 9B, an etching process that forms an opening PR passing through the material layers M1 and M3 is performed. The opening PR may have a circular or elliptical shape in the XY plane.

To form the opening PR in a direction perpendicular to the material layers M1 and M3, an etching process is performed, for example, using a dry etching method. For example, an anisotropic dry etching process may be performed. The opening PR is formed having the first width W1 or diameter. For example, a space between the first material layers M1 is an opening PR at the first width W1 or diameter, and the opening PR is formed such that a space between the third material layers M3 has the first width W1. When the opening PR is formed, a surface of each of the material layers M1 and M3 is exposed through the opening PR.

Referring to FIG. 9C, an etching process is performed that removes a section of the third material layers M3 exposed through the opening PR. To selectively remove a section of the third material layers M3, an etchant having a higher selectivity for the third material layers M3 than the selectivity of the first material layers M1 is used. Regions where a section of the third material layers M3 is removed are referred to as first recesses 1RC. For example, the third material layers M3 are removed by a first distance D1.

Referring to FIG. 9D, the tunnel insulating layers TX are selectively formed on a surface of the third material layers M3 exposed through the first recesses 1RC. The tunnel insulating layer TX may be formed using an oxidation process. The tunnel insulating layer TX is formed within the first recesses 1RC from a section of the third material layers M3 by the oxidation process.

Referring to FIG. 9E, the charge trap layers CT is formed in the remaining space of the first recesses 1RC of FIG. 9D where the tunnel insulating layers TX are formed. The charge trap layers CT may be formed including polysilicon. For example, after the polysilicon for the charge trap layer CT is formed within the opening PR to fill the first recesses 1RC, polysilicon may form on the surfaces of the first material layers M1. An etching process may be performed to remove the polysilicon formed on the surfaces of the first material layers M1 as the polysilicon filled in the first recesses 1RC remains. Because the charge trap layers CT are formed in a region where the third material layers M3 are positioned, each of the charge trap layers CT has the second thickness T2.

Referring to FIG. 9F, the protrusions PT are selectively formed on surfaces of the charge trap layers CT exposed through the opening PR. For example, forming the protrusions PT may be performed utilizing an in-situ method after forming the charge trap layers CT. The protrusions PT may be formed utilizing a method in which the protrusions PT are grown from respective charge trap layers CT. Because the area at a center of the protrusion PT in the Z direction is greater than an area at a top edge and a bottom edge of the charge trap layer CT exposed through the opening PR, the protrusion PT grows faster at the center of the charge trap layers CT. As a result, the protrusions PT are formed having a curved surface. Because the protrusions PT extend in the direction of the central axis AX of the opening PR, a width between the protrusions PR positioned on the same layer in the Z direction is the fourth width W4 that is narrower than the first width W1.

Referring to FIG. 9G, the blocking layer BX is formed along a surface of the protrusions PT and the first material layers M1 exposed in the opening PR. The blocking layer BX includes the blocking layers B1 to B3. For example, the first blocking layer B1 is formed along a surface of the first material layers M1 and the protrusions PT are exposed through the opening PR. The second blocking layer B2 is formed along a surface of the first blocking layer B1 exposed through the opening PR. The third blocking layer B3 is formed along a surface of the second blocking layer B2 exposed through the opening PR. Because the blocking layers B1 to B3 are formed along a surface of the protrusions PT and the first material layers M1, the blocking layers B1 to B3 formed on the protrusions PT have a convex curved surface. The blocking layer BX may be formed in a cylindrical shape with an uneven side surface.

Referring to FIG. 9H, the channel layer CH is formed along an innermost surface of the blocking layer BX exposed through the opening PR. For example, the channel layer CH is formed along a surface of the third blocking layer B3. Because the blocking layer BX is formed in a cylindrical shape, the channel layer CH is also be formed in a cylindrical shape. In this example, the innermost surface of the channel layer CH is cylindrical and straight in the Z direction, whereas the outermost surface of the channel layer CH is uneven and follows the contours of the third blocking layer B3, including flat sections alternating with concave sections that mate with convex sections of the third blocking layer B3. The channel layer CH may be formed including polysilicon. The channel layer CH between the protrusions PT is formed to be thicker than each of the blocking layers B1 to B3 in the X direction.

Referring to FIG. 9I, the core pillar CP is formed in a region surrounded by the channel layer CH. The core pillar CP may include an insulating material or a conductive material and is filled into a region surrounded by the channel layer CH. Accordingly, the cell plug CPL including the blocking layer BX, the channel layer CH, and the core pillar CP are formed.

Referring to FIG. 9J, as shown in FIG. 2, a trench is formed in a slit region SLT that divides the memory blocks, and an etching process is performed that removes the third material layers M3 exposed through the trench. Regions where the third material layers M3 are removed are referred to as second recesses 2RC. Areas of the first material layers M1 and areas of the tunnel insulating layers TX are exposed through the second recesses 2RC.

Referring to FIG. 9K, the second material layers M2 are formed in the second recesses 2RC of FIG. 9J. For example, the second material layers M2 fill the second recesses 2RC through the slit region SLT described with reference to FIG. 9J and FIG. 2.

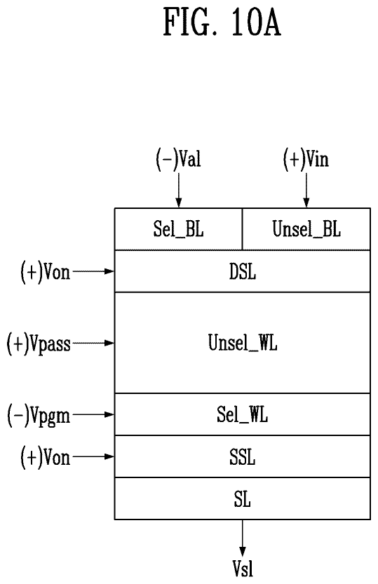

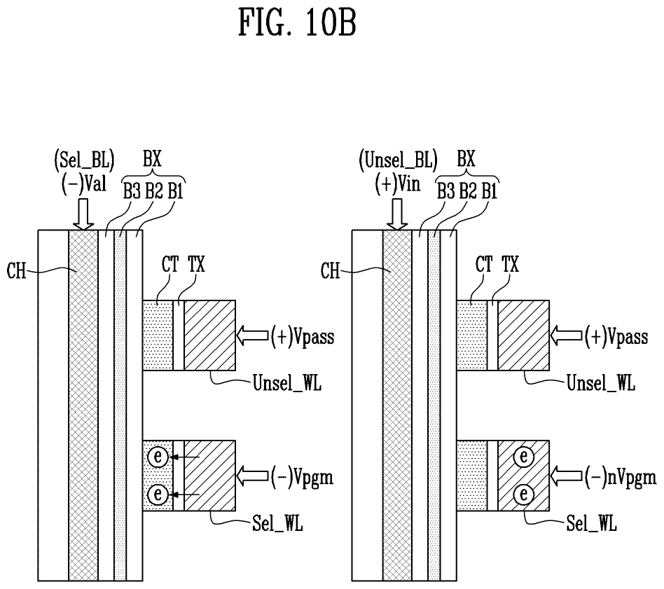

FIG. 10A and FIG. 10B are diagrams illustrating views of a memory block and a section of a first structure during a program operation of a program method according to an embodiment of the present disclosure.

Referring to FIG. 10A, the program operation of the memory block is performed in a page unit. For example, the program operation is performed in the page unit connected to a selected word line Sel_WL. During the program operation of the memory block, a program allowable voltage Val is applied to selected bit lines Sel_BL, and a program inhibit voltage Vin is applied to unselected bit lines Unsel_BL. According to an embodiment, the program allowable voltage Val is 0V or a negative voltage (−) lower than 0V, and the program inhibit voltage Vin is a positive voltage (+) higher than 0V. A source voltage Vsl is applied to the source line SL. The source voltage Vsl is at a ground voltage or a negative voltage. A turn-on voltage Von s applied to the drain select line DSL and the source select line SSL. The turn-on voltage Von is a positive voltage (+) higher than 0V. A program voltage Vpgm is applied to the selected word lines Sel_WL, and a pass voltage Vpass is applied to the unselected word lines Unsel_WL. According to an embodiment, the program voltage Vpgm is a negative voltage (−) lower than 0V, and the pass voltage Vpass is a positive voltage (+) higher than 0V.

As described, the program voltage Vpgm applied to the selected word line Sel_WL is set to a negative voltage (−) as described with reference to FIG. 10B.

Referring to FIG. 10B, a section of the first structure shown in FIG. 4A is shown as an example, although the same program operation may be performed in the second structure shown in FIG. 7.

According to an embodiment, because the tunnel insulating layers TX are positioned between the charge trap layers CT and the word lines Sel_WL and Unsel_WL, and the blocking layer BX is positioned between the charge trap layers CT and the channel layer CH, electrons (“e”) are tunneled between the charge trap layers CT and the word lines Sel_WL and Unsel_WL. When the program allowable voltage Val at a negative voltage (−) level is applied to the selected bit line Sel_BL, a potential of the channel layer CH is decreased. When the program voltage Vpgm at a negative voltage (−) level is applied to the selected word line Sel_WL, the electrons e included in the selected word line Sel_WL tunnel through the tunnel insulating layer TX and move into the charge trap layer CT. The negative voltage (−) level of the program voltage Vpgm may vary. Because the blocking layer BX blocks the electrons e in the charge trap layer CT nearest to the selected word line Sel_WL from moving into the channel layer CH, the electrons e are trapped in the charge trap layer CT. Because the consecutive charge trap layers CT in the Z direction are spaced apart from each other, the electrons e trapped in the charge trap layer CT are maintained in the charge trap layer CT.

Because the pass voltage Vpass at a positive voltage (+) level is applied to the unselected word line Unsel_WL, electrons do not flow into the charge trap layer CT nearest to the unselected word line Unsel_WL.

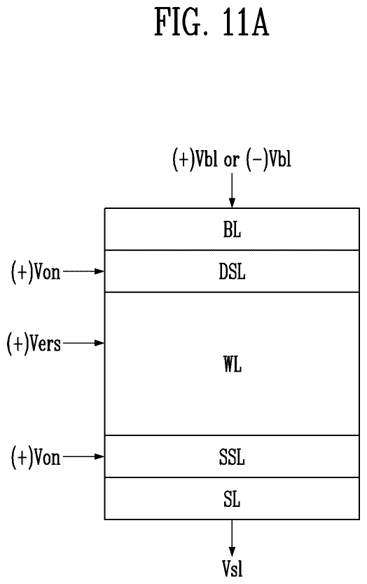

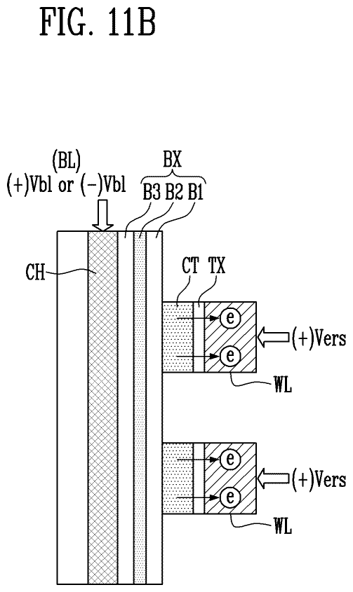

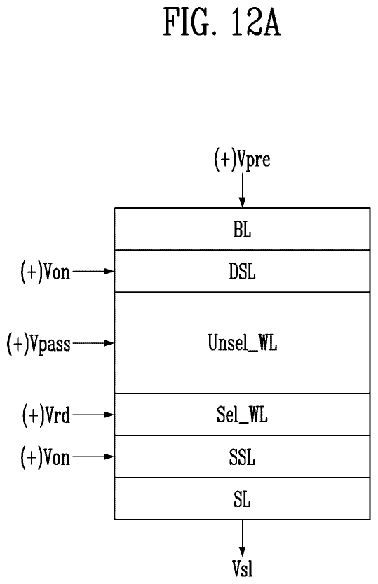

FIG. 11A and FIG. 11B are diagrams illustrating views of a memory block and a section of a first structure during an erase operation of an erase method according to an embodiment of the present disclosure.

Referring to FIG. 11A, the erase operation of the memory block is performed in a memory block unit. During the erase operation of the memory block, a bit line voltage Vbl at a positive voltage (+) or negative voltage (−) level is applied to the bit lines BL. The source voltage Vsl is applied to the source line SL. The source voltage Vsl is a ground voltage, a negative voltage, or a positive voltage. The turn-on voltage Von is applied to the drain select line DSL and the source select line SSL. The turn-on voltage Von is a positive voltage (+) higher than 0V. An erase voltage Vers is applied to the word lines WL. According to an embodiment, the erase voltage Vers is a positive voltage (−) higher than 0V. A positive voltage (+) level of the erase voltage Vers may vary.

As described, the erase voltage Vers applied to the word lines WL is at a positive voltage (+) as described with reference to FIG. 11B.

Referring to FIG. 11B, as described with reference to FIG. 10B, because the electrons e are trapped in the charge trap layers CT of the programmed memory cells, the electrons e trapped in the charge trap layers CT may leak or cross into the word lines WL through the tunnel insulating layers TX during the erase operation. To move the electrons e from the charge trap layers CT into the word lines WL, the erase voltage Vers at the positive voltage (+) level is applied to the word lines WL, and a bit line voltage Vbl at a positive voltage (+) or negative voltage (−) level is applied to the channel layer CH.

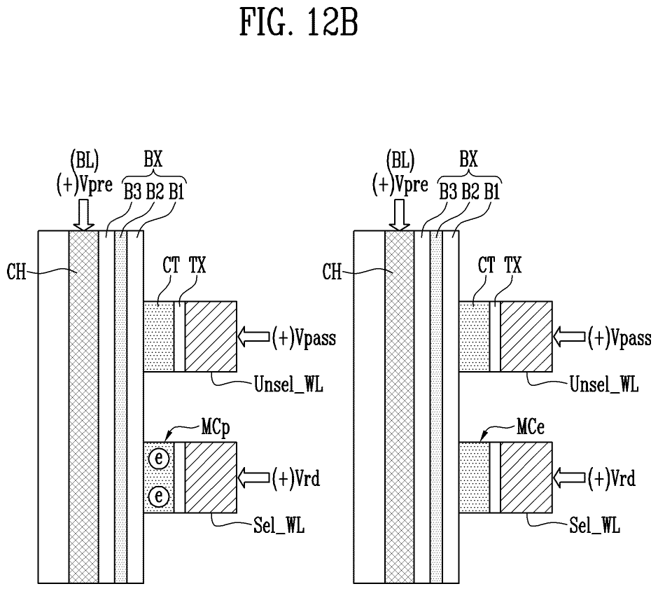

FIG. 12A and FIG. 12B are diagrams illustrating views of a memory block and a section of a first structure during a read operation of a read method according to an embodiment of the present disclosure.

Referring to FIG. 12A, the read operation of the memory block is performed in a page unit. For example, the read operation is performed in the page unit connected to the selected word line Sel_WL. During the read operation of the memory block, a precharge voltage Vpre at a positive voltage (+) level is applied to the bit lines BL. The source voltage Vsl is applied to the source line SL. The source voltage Vsl is at a ground voltage or a negative voltage. The turn-on voltage Von is applied to the drain select line DSL and the source select line SSL. The turn-on voltage Von is set to a positive voltage (+) higher than 0V. The program voltage Vpgm is applied to the selected word lines Sel_WL, and the pass voltage Vpass is applied to the unselected word lines Unsel_WL. According to an embodiment, a read voltage Vrd is at a positive voltage (+) higher than 0V, and the pass voltage Vpass is at a positive voltage (+) higher than 0V. The read voltage Vrd may vary according to logical page data.

Referring to FIG. 12B, because the electrons e are trapped in the charge trap layer CT of a programmed memory cell MCp, a threshold voltage of the programmed memory cell MCp is higher than a threshold voltage of erased memory cell MCe. To determine a state of the memory cells, the precharge voltage Vpre at a positive voltage (+) level is applied to the bit lines BL, and a potential of the channel layers CH is increased. The read voltage Vrd is applied to the selected word line Sel_WL, and the pass voltage Vpass is applied to the unselected word line Unsel_WL. The pass voltage Vpass is a voltage used to form a channel in the channel layer CH, and the read voltage Vrd is a voltage used to determine a threshold voltage of the memory cells connected to the selected word line Sel_WL. For example, among the memory cells connected to the selected word line Sel_WL, a channel is not formed in a memory cell for which a threshold voltage is higher than the read voltage Vrd, and a channel is formed in a memory cell for which a threshold voltage is lower than the read voltage Vrd. As a result, data of the memory cells is read by sensing a voltage change at the bit lines BL.

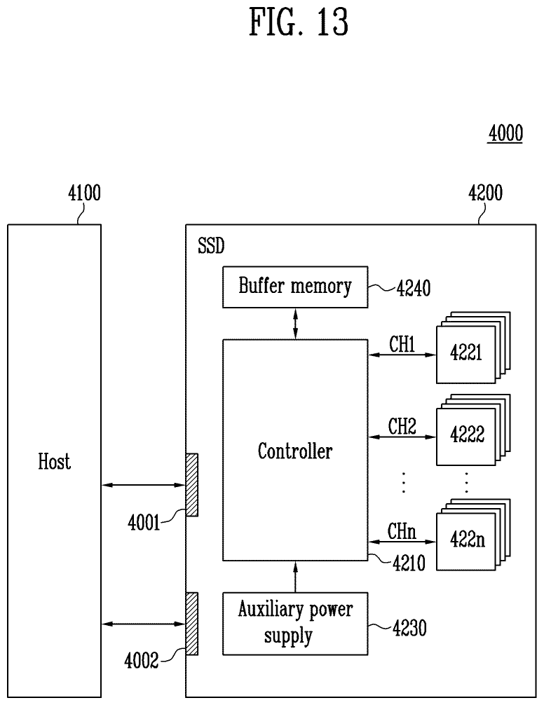

FIG. 13 is a diagram illustrating a solid state drive SSD system including the memory device of the present disclosure.

Referring to FIG. 13, the SSD system 4000 includes a host 4100 and an SSD 4200. The SSD 4200 may exchange a signal with the host 4100 through a signal connector 4001 and receive power through a power connector 4002. The SSD 4200 includes a controller 4210, memory devices 4221 to 422n, an auxiliary power supply 4230, and a buffer memory 4240.

According to an embodiment of the present disclosure, each of the memory devices 4221 to 422n is configured similarly to the memory device 100 described with reference to FIG. 1, FIG. 4A, and/or FIG. 7.

The controller 4210 controls the plurality of memory devices 4221 to 422n in response to signals received from the host 4100. For example, the signals are signals based on an interface between the host 4100 and the SSD 4200. The signals may be configured according to at least one of interfaces such as universal serial bus (USB), multimedia card (MMC), embedded MMC (eMMC), peripheral component interconnection (PCI), PCI express (PCI-E), advanced technology attachment (ATA), serial-ATA, parallel-ATA, small computer system interface (SCSI), enhanced small disk interface (ESDI), integrated drive electronics (IDE), FireWire, universal flash storage (UFS), Wi-Fi, Bluetooth, NVMe, and so forth.

The auxiliary power supply 4230 is connected to the host 4100 through the power connector 4002. The auxiliary power supply 4230 receives a power voltage from the host 4100 and may be charged. The auxiliary power supply 4230 provides the power voltage to the SSD 4200 when power supply from the host 4100 is unreliable or of poor quality. For example, the auxiliary power supply 4230 may be positioned in the SSD 4200 or may be located outside the SSD 4200. For example, the auxiliary power supply 4230 may be located on a main board and may provide auxiliary power to the SSD 4200.

The buffer memory 4240 is a buffer memory of the SSD 4200. For example, the buffer memory 4240 temporarily stores data received from the host 4100 or data received from the memory devices 4221 to 422n or temporarily stores metadata (for example, a mapping table) of the memory devices 4221 to 422n. The buffer memory 4240 may include a volatile memory such as a DRAM, an SDRAM, a DDR SDRAM, an LPDDR SDRAM, and so forth, or a nonvolatile memory such as an FRAM, a ReRAM, an STT-MRAM, a PRAM, and so forth.

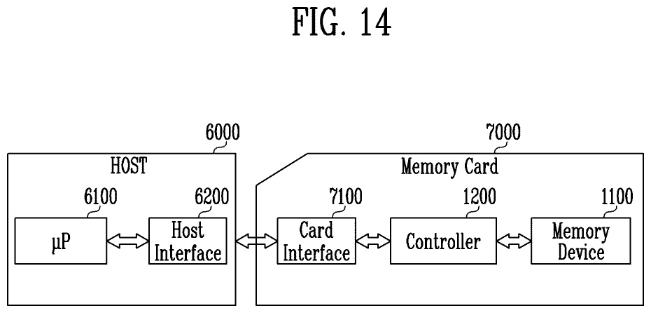

FIG. 14 is a diagram illustrating a memory card system including a memory device of the present disclosure.

Referring to FIG. 14, the memory system 7000 may be implemented as a memory card or a smart card. The memory system 7000 includes a memory device 1100, a controller 1200, and a card interface 7100.

The memory device 1100 may be configured similarly to the memory device 100 shown in FIG. 1, FIG. 4A, and/or FIG. 7.

The controller 1200 controls data exchange between the memory device 1100 and the card interface 7100. According to an embodiment, the card interface 7100 may be a secure digital (SD) card interface, a multi-media card (MMC) interface, and so forth.

The card interface 7100 interfaces data exchange between a host 6000 and the controller 1200 according to a protocol of the host 6000. According to an embodiment, the card interface 7100 may support a universal serial bus (USB) protocol, an inter chip (IC)-USB protocol, and so forth. The card interface 7100 includes, for example, hardware capable of supporting a protocol that is used by the host 6000, software installed in the hardware, and/or a signal transmission method.

When the memory system 7000 is connected to a host interface 6200 of the host 6000 such as a PC, a tablet PC, a digital camera, a digital audio player, a mobile phone, a console video game hardware, or a digital set-top box. The interface 6200 performs data communication with the memory device 1100 through the card interface 7100 and the controller 1200 under control of a microprocessor (UP) 6100.

Although the detailed embodiments of the present disclosure are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A memory device comprising:
a channel layer;
a blocking layer surrounding the channel layer;
a plurality of charge trap layers spaced apart from each other and arranged along the blocking layer;
a plurality of tunnel insulating layers, each of the plurality of tunnel insulating layers contacting a different one of the plurality of charge trap layers; and
a plurality of gate lines, each of the plurality of gate lines contacting a different one of the plurality of tunnel insulating layers;
wherein each of the plurality of tunnel insulating layers is positioned between a different one of the plurality of charge trap layers and a different one of the plurality of gate lines.

2. The memory device of claim 1, wherein the channel layer extends in a direction perpendicular to a substrate.

3. The memory device of claim 1, wherein the blocking layer surrounds the channel layer.

4. The memory device of claim 1, wherein the blocking layer comprises:
a first blocking layer contacting the plurality of charge trap layers;
a second blocking layer contacting the first blocking layer; and
a third blocking layer positioned between the second blocking layer and the channel layer.

5. The memory device of claim 4, wherein the first and third blocking layers are formed including an oxide material, and
the second blocking layer is formed including a nitride material.

6. The memory device of claim 4, wherein the first and third blocking layers are formed including a high-K material, and
the second blocking layer is formed including a low-K material.

7. The memory device of claim 1, wherein the charge trap layer is formed including a nitride material.

8. The memory device of claim 1, wherein the charge trap layer is formed including at least one of silicon nitride SiN and silicon-oxynitride SiON.

9. The memory device of claim 1, further comprising insulating materials positioned between consecutive charge trap layers of the plurality of charge trap layers and along the surface of the blocking layer.

10. The memory device of claim 1, wherein each of the plurality of charge trap layers comprises a protrusion extending toward the blocking layer.

11. The memory device of claim 10, wherein the protrusions and the plurality of charge trap layers are formed including a same material.

12. The memory device of claim 10, wherein an interface where the protrusions contact the blocking layer is a curved surface.

13. A memory device comprising:
a blocking layer surrounding a channel layer;
a plurality of charge trap layers spaced apart and arranged along a surface of the blocking layer, each of the plurality of charge trap layers comprising a protrusion extending toward the blocking layer;
a plurality of tunnel insulating layers, each of the plurality of tunnel insulating layers contacting a different one of the plurality of charge trap layers; and
a plurality of gate lines, each of the plurality of gate lines contacting a different one of the plurality of tunnel insulating layers.
